(19) United States
(12) Patent Application Publication
(10) Pub. No.: US 2025/0024713 A1
(43) Pub. Date: Jan. 16, 2025

(54) DISPLAY PANEL AND METHOD FOR MANUFACTURING THE SAME

(71) Applicant: Samsung Display Co., Ltd., Yongin-si (KR)

(72) Inventors: HYUNEOK SHIN, Yongin-si (KR); SANGWOOK LEE, Yongin-si (KR); INSEOK LIM, Yongin-si (KR); YUNG BIN CHUNG, Yongin-si (KR)

(21) Appl. No.: 18/770,523

(22) Filed: Jul. 11, 2024

(30) Foreign Application Priority Data
Jul. 13, 2023 (KR) 10-2023-0091051

(51) Int. Cl. H10K 59/122; H10K 50/155; H10K 59/131; H10K 59/80; H10K 102/00

(52) U.S. Cl. CPC H10K 59/122; H10K 50/155; H10K 59/131; H10K 59/873; H10K 2102/351

(57) ABSTRACT

The present disclosure relates to a display panel and a method for manufacturing the same. The display panel according to one or more embodiments of the present disclosure may include a base layer, a pixel-defining film above the base layer, and defining an emission-opening portion, a partition wall including a first partition wall layer above the pixel-defining film, and including a lower partition wall layer including an insulation material, and an upper partition wall layer including a conductive material above the lower partition wall layer, and a second partition wall layer above the first partition wall layer and defining a partition-wall-opening portion overlapping the emission-opening portion, and a light-emitting element including an anode, an intermediate layer contacting the lower partition wall layer and spaced apart from the upper partition wall layer above the anode, and a cathode above the intermediate layer.

### CROSS-REFERENCE TO RELATED APPLICATIONS

The present application claims priority to, and the benefit of, Korean Patent Application No. 10-2023-0091051, filed on Jul. 13, 2023, in the Korean Intellectual Property Office, the entire disclosure of which is incorporated herein by reference.

### BACKGROUND

One or more aspects of the present disclosure relate to a display panel with improved display quality.

Display devices, such as televisions, monitors, smartphones and tablet computers, which provide users with images, include display panels that display the images. Various display panels, such as liquid crystal display panels, organic light-emitting display panels, electro wetting display panels, and electrophoretic display panels, are developed as the display panels.

An organic light-emitting display panel may include an anode, a cathode, and an emission pattern. The emission pattern may be separated in each of emission areas, and the cathode may supply a common voltage to each of the emission areas.

### SUMMARY

The present disclosure provides a display panel capable of preventing or reducing leakage current from being generated to provide improved display quality, and a method for manufacturing the display panel.

One or more embodiments of the present disclosure provide a display panel may include a base layer, a pixel-defining film above the base layer, and defining an emission-opening portion, a partition wall including a first partition wall layer above the pixel-defining film, and including a lower partition wall layer including an insulation material, and an upper partition wall layer including a conductive material above the lower partition wall layer, and a second partition wall layer above the first partition wall layer and defining a partition-wall-opening portion overlapping the emission-opening portion, and a light-emitting element including an anode, an intermediate layer contacting the lower partition wall layer and spaced apart from the upper partition wall layer above the anode, and a cathode above the intermediate layer.

The lower partition wall layer may include amorphous silicon (a-Si), and the upper partition wall layer may include n⁺ silicon (n⁺ Si).

The intermediate layer may include at least one organic layer doped with a p-type dopant.

The intermediate layer may include a hole transport region including the organic layer doped with the p-type dopant above the anode, an emission layer above the hole transport region, and an electron transport region above the emission layer.

The intermediate layer may include emission structures above the anode, and a charge generation layer between the emission structures and including the organic layer doped with the p-type dopant.

The lower partition wall layer may have a thickness that is less than about 0.5 times a thickness of the first partition wall layer.

The cathode may contact the upper partition wall layer, and may be electrically connected to the partition wall.

The second partition wall layer may include a tip portion protruding from the first partition wall layer toward the partition-wall-opening portion.

The second partition wall layer may include at least one of molybdenum or titanium.

The display panel may further include a thin film encapsulation layer including thin films above the light-emitting element, and including a lower inorganic encapsulation pattern covering the light-emitting element and contacting the partition wall.

The lower inorganic encapsulation pattern may include silicon nitride (SiNₓ).

The partition-wall-opening portion may include a first region in which the light-emitting element is located, and a second region having a width that is less than a width of the first region, wherein the first partition wall layer has a first inner side surface defining the first region, and wherein the second partition wall layer has a second inner side surface defining the second region.

In one or more embodiments of the present disclosure, a display panel may include a base layer, a pixel-defining film above the base layer and defining an emission-opening portion, a partition wall above the pixel-defining film, defining a partition-wall-opening portion corresponding to the emission-opening portion, and including a lower partition wall layer including amorphous silicon (a-Si), an upper partition wall layer above the lower partition wall layer, and including n⁺ silicon (n⁺ Si), and a second partition wall layer above the upper partition wall layer, and including a tip portion protruding from the lower partition wall layer and the upper partition wall layer toward the partition-wall-opening portion, and a light-emitting element in the partition-wall-opening portion in plan view, and including an anode, an intermediate layer above the anode, and a cathode above the intermediate layer.

The intermediate layer may contact the lower partition wall layer and may be spaced apart from the upper partition wall layer, and the cathode may contact the upper partition wall layer.

The display panel may further include a sacrificial pattern between the anode and the pixel-defining film, and defining a sacrificial-opening portion overlapping the emission-opening portion.

The display panel may further include a thickness of the lower partition wall layer is less than a thickness of the upper partition wall layer.

In one or more embodiments of the present disclosure, a method for manufacturing a display panel may include providing a preliminary display panel including a base layer, an anode above the base layer, and a pixel-defining film above the base layer and covering the anode, forming a first preliminary partition wall layer by depositing an insulation material and a conductive material having substantially equal etch selectivity above the preliminary display panel, forming a second preliminary partition wall layer above the preliminary display panel, etching the first preliminary partition wall layer and the second preliminary partition wall layer to form a partition wall defining a partition-wall-opening portion, and forming an emission pattern and a cathode in the partition-wall-opening portion.

The insulation material may include amorphous silicon (a-Si), and the conductive material may include n⁺ silicon (n⁺ Si).

The second preliminary partition wall layer may include a conductive material having a lower etch rate than the first preliminary partition wall layer.

The method of manufacturing a display panel according to one or more embodiments may further include etching the first preliminary partition wall layer and the second preliminary partition wall layer at a substantially same time through dry etching.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1 is a perspective view of a display device according to one or more embodiments of the present disclosure;

FIG. 2 is an exploded perspective view of a display device according to one or more embodiments of the present disclosure;

FIG. 3 is a cross-sectional view of a display module according to one or more embodiments of the present disclosure;

FIG. 4 is a plan view of a display panel according to one or more embodiments of the present disclosure;

FIG. 5 is an equivalent circuit diagram of a pixel according to one or more embodiments of the present disclosure;

FIG. 6 is an enlarged plan view of a portion of a display area of a display panel according to one or more embodiments of the present disclosure;

FIG. 7 is a cross-sectional view of the display panel according to one or more embodiments of the present disclosure taken along the line I-I′ in FIG. 4;

FIGS. 8A, and 8B are each an enlarged view illustrating area AA in FIG. 7;

FIG. 9 is a cross-sectional view of the display panel according to one or more embodiments of the present disclosure taken along the line II-II′ in FIG. 6; and

FIGS. 10A to 10I are cross-sectional views illustrating some of operations of a method for manufacturing a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

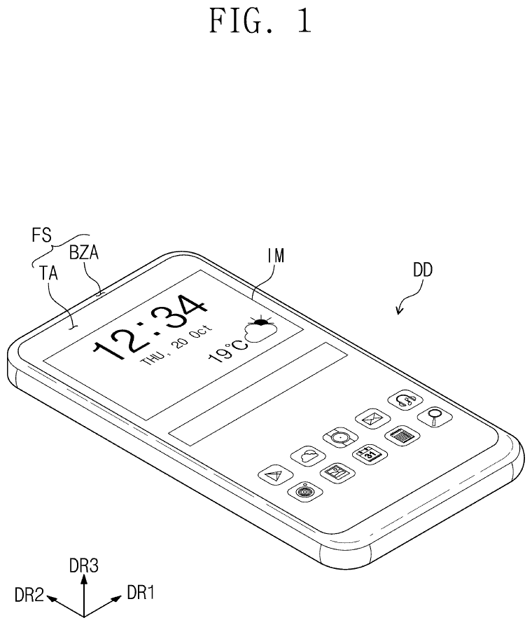

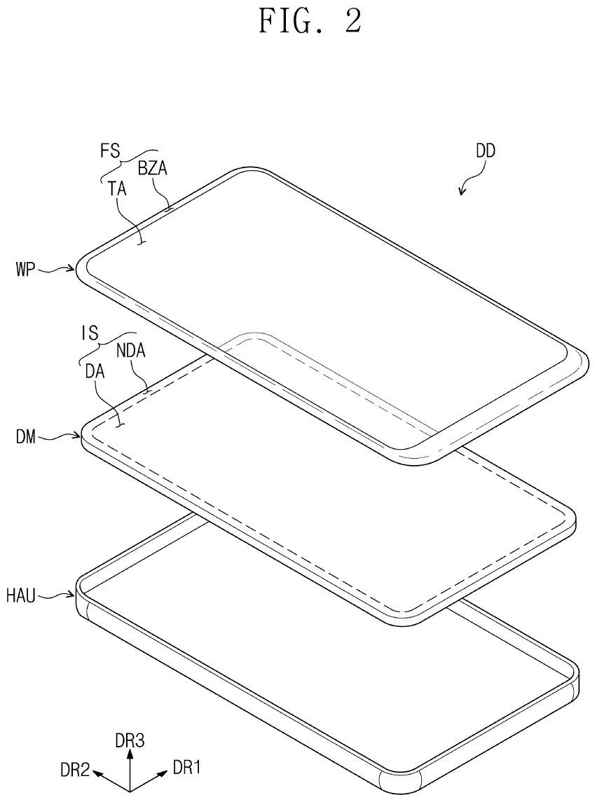

FIG. 1 is a perspective view of a display device DD according to one or more embodiments of the present disclosure. FIG. 2 is an exploded perspective view of the display device DD according to one or more embodiments of the present disclosure.

In one or more embodiments, the display device DD may be a large-sized display device, such as a television, a monitor, or an outdoor billboard. The display device DD may also be a small and medium-sized display device, such as a personal computer, a notebook computer, a personal digital assistant, a vehicle navigation unit, a game console, a smartphone, a tablet computer, or a camera. However, the foregoing devices are examples, and the display device DD may also be employed as another display device unless departing from the present disclosure. FIGS. 1 and 2 illustrate a smartphone as an example of the display device DD.

Referring to FIGS. 1 and 2, the display device DD may display an image IM in a third direction DR3 on a display surface FS parallel to each of a first direction DR1 and a second direction DR2. The third direction DR3 may be a normal direction to a plane defined by the first direction DR1 and the second direction DR2. The image IM may include not only a dynamic image but also a still image. FIG. 1 illustrates a clock window and application icons as an example of the image IM. The display surface FS on which the image IM is displayed may correspond to a front surface of the display device DD.

In one or more embodiments, a front surface (or top surface) and a rear surface (or bottom surface) of each member is defined based on a direction in which the image IM is displayed. The front surface and the rear surface may oppose each other in the third direction DR3, and a normal direction to each of the front surface and the rear surface may be parallel to the third direction DR3. Directions indicated by the first to third directions DR1, DR2, and DR3 are relative concepts and may be changed to other directions. The phrase “on a plane” used herein may mean a state when viewed in the third direction DR3.

The display device DD may include a window WP, a display module DM, and a housing HAU. The window WP and the housing HAU may be coupled to each other to constitute an outer appearance of the display device DD.

The window WP may include an optically transparent insulation material. For example, the window WP may include glass or plastic. The front surface of the window WP may define the display surface FS of the display device DD. The display surface FS may include a transmission area TA and a bezel area BZA. The transmission area TA may be an optically transparent area. For example, the transmission area TA may be an area having a visible light transmittance of about 90% or higher.

The bezel area BZA may be an area having a relatively low light transmittance compared to the transmission area TA. The bezel area BZA may define a shape of the transmission area TA. The bezel area BZA may be adjacent to the transmission area TA and surround the transmission area TA. However, this is illustrated as an example, and the bezel area BZA of the window WP may be omitted. The window WP may include at least one functional layer of an anti-fingerprint layer, a hard coating layer, or an anti-reflection layer, and is not limited to any one embodiment.

The display module DM may be located below the window WP. The display module DM may be a component that substantially generates the image IM. The image IM generated by the display module DM may be displayed on a display surface IS of the display module DM, and externally visible to a user through the transmission area TA.

The display module DM may include a display area DA and a non-display area NDA. The display area DA may be an area that is activated in response to an electrical signal. The non-display area NDA may be adjacent to the display area DA. The non-display area NDA may surround the display area DA. The non-display area NDA may be an area covered by the bezel area BZA, and may be non-visible externally.

The housing HAU may be coupled to the window WP. The housing HAU may be coupled to the window WP to provide a preset inner space. The display module DM may be accommodated in the inner space.

The housing HAU may include a material having relatively high rigidity. For example, the housing HAU may include a plurality of frames and/or plates, each of which includes glass, plastic, or metal, or is made of a combination thereof. The housing HAU may stably protect components of the display module DM accommodated in the inner space from external impact.

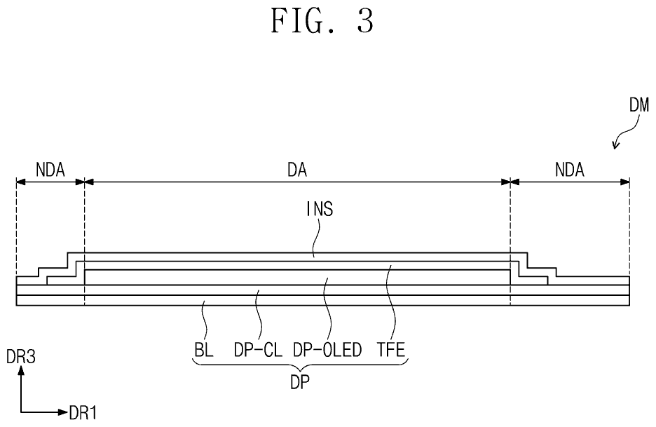

FIG. 3 is a cross-sectional view of a display module DM according to one or more embodiments of the present disclosure.

Referring to FIG. 3, the display module DM may include a display panel DP and an input sensor INS. The display device DD (see FIG. 1) according to one or more embodiments of the present disclosure may further include a protective member located on a bottom surface of the display panel DP, or an anti-reflection member and/or a window member that are located on a top surface of the input sensor INS.

The display panel DP may be a light-emitting display panel. However, this is an example, and the present disclosure is not particularly limited thereto. For example, the display panel DP may be an organic light-emitting display panel or an inorganic light-emitting display panel. An emission layer in the organic light-emitting display panel may include an organic light-emitting material. An emission layer in the inorganic light-emitting display panel may include a quantum dot, a quantum rod, or a micro-LED. Hereinafter, the display panel DP is described as the organic light-emitting display panel.

The display panel DP may include a base layer BL. The display panel DP may include a circuit element layer DP-CL, a display element layer DP-OLED, and a thin film encapsulation layer TFE, each of which may be located on the base layer BL (as used herein, “on” may mean “above”). The input sensor INS may be located directly on the thin film encapsulation layer TFE. In the present disclosure, “a component A being located directly on a component B” means that an adhesive layer is not positioned between the component A and the component B.

The base layer BL may include at least one plastic film. The base layer BL may be a flexible substrate, and may include a plastic substrate, a glass substrate, a metal substrate, an organic/inorganic composite material substrate, or the like. The display area DA and the non-display area NDA that are described with reference to FIG. 2 may be similarly defined on the base layer BL.

The circuit element layer DP-CL may include at least one insulation layer and a circuit element. The insulation layer may include at least one inorganic layer and at least one organic layer. The circuit element may include signal lines, a driving circuit of a pixel, and the like.

The display element layer DP-OLED may include a partition wall and a light-emitting element. The light-emitting element may include an anode, an intermediate layer, and a cathode.

The thin film encapsulation layer TFE may include a plurality of thin films. Some of the thin films may be positioned to improve optical efficiency, and some of the thin films may be positioned to protect organic light-emitting diodes.

The input sensor INS obtains coordinate information of an external input. The input sensor INS may have a multilayer structure. The input sensor INS may include a conductive layer having a single-layer structure or a multilayer structure. In addition, the input sensor INS may include an insulation layer having a single-layer or multilayer structure. The input sensor INS may detect an external input by using a capacitance method. However, this is an example, and the present disclosure is not limited thereto. For example, in one or more embodiments, the input sensor INS may detect an external input by using an electromagnetic induction method or a pressure detection method. In one or more other embodiments of the present disclosure, the input sensor INS may be omitted.

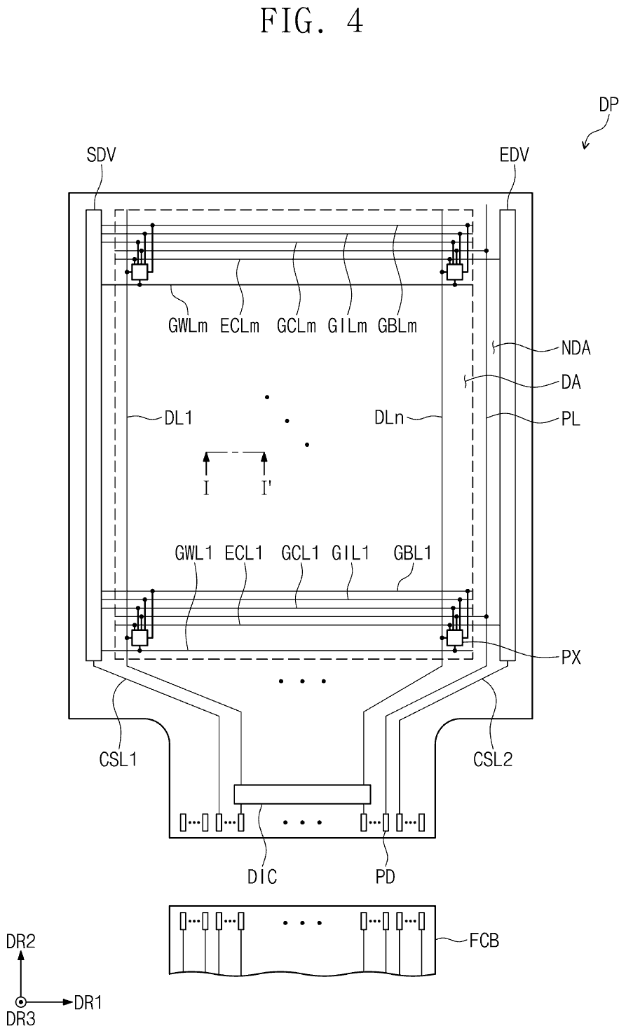

FIG. 4 is a plan view of a display panel DP according to one or more embodiments of the present disclosure.

Referring to FIG. 4, a display area DA and a non-display area NDA around the display area DA may be defined on the display panel DP. The display area DA and the non-display area NDA may be divided according to whether pixels PX are located or not. The pixels PX may be located in the display area DA, and the pixels PX may not be located in the non-display area NDA.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, a scan driver SDV, a data driver, an emission driver EDV, a driving chip DIC, and pads PD. Here, m and n represent natural numbers of 2 or greater. The data driver may be a circuit included in a driving chip DIC.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 to be electrically connected to the scan driver SDV. The data lines DL1 to DLn may extend in the second direction DR2 to be electrically connected to the driving chip DIC. The emission control lines ECL1 to ECLm may extend in the first direction DR1 to be electrically connected to the emission driver EDV.

The drive voltage line PL may include a portion extending in the first direction DR1 and a portion extending in the second direction DR2. The portion extending in the first direction DR1 and the portion extending in the second direction DR2 may be located on different layers. The drive voltage line PL may supply a drive voltage to the pixels PX.

The first control line CSL1 may be connected to the scan driver SDV. The second control line CSL2 may be connected to the emission driver EDV.

The driving chip DIC, the drive voltage line PL, the first control line CSL1, and the second control line CSL2 may be electrically connected to the pads PD. A flexible circuit film FCB may be electrically connected to the pads PD through an anisotropic conductive adhesive layer. The pads PD may be pads for connecting the flexible circuit film FCB to the display panel DP. The pads PD may be connected to corresponding pixels PX through the drive voltage line PL, the first control line CSL1, and the second control line CSL2.

In addition, the pads PD may further include input pads. The input pads may be pads for connecting the flexible circuit film FCB to the input sensor INS (see FIG. 3). However, the present disclosure is not limited thereto, and the input pads may be located in the input sensor INS (see FIG. 3) and connected to a separate circuit board from the pads PD. Alternatively, the input sensor INS may be omitted, and the pads PD may not further include input pads.

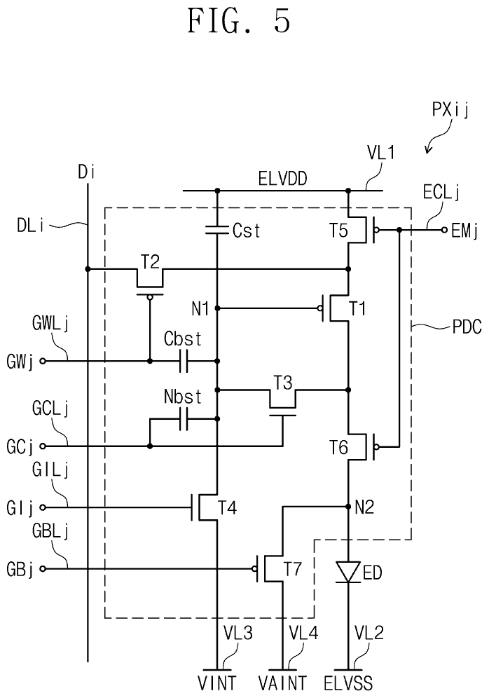

FIG. 5 is an equivalent circuit diagram of a pixel PXij according to one or more embodiments of the present disclosure.

As an example, FIG. 5 illustrates an equivalent circuit diagram of one pixel PXij of the plurality of pixels PX (see FIG. 4). Because the plurality of pixels PX have substantially the same circuit structure, the circuit structure of the pixel PXij will be described, and the specific description of the other pixels PX will be omitted.

Referring to FIGS. 4 and 5, the pixel PXij is connected to an i-th data line DLi of the data lines DL1 to DLn, a j-th initialization scan line GILj of the initialization scan lines GIL1 to GILm, a j-th compensation scan line GCLj of the compensation scan lines GCL1 to GCLm, a j-th write scan line GWLj of the write scan lines GWL1 to GWLm, a j-th black scan line GBLj of the black scan lines GBL1 to GBLm, a j-th emission control line ECLj of the emission control lines ECL1 to ECLm, first and second drive voltage lines VL1 and VL2, and first and second initialization voltage lines VL3 and VL4. Here, i represents an integer of 1 to n, and j represents an integer of 1 to m.

The pixel PXij may include a light-emitting element ED and a pixel circuit PDC. The light-emitting element ED may be a light-emitting diode. As an example of one or more embodiments of the present disclosure, the light-emitting element ED may be an organic light-emitting diode including an organic emission layer, but is not particularly limited thereto. The pixel circuit PDC may control an amount of current flowing through the light-emitting element ED in response to a i-th data signal Di. The light-emitting element ED may emit light at preset luminance corresponding to the amount of current supplied from the pixel circuit PDC.

The pixel circuit PDC may include first to seventh transistors T1, T2, T3, T4, T5, T6, and T7, and first to third capacitors Cst, Cbst, and Nbst. The configuration of the pixel circuit PDC according to one or more embodiments of the present disclosure is not limited to the one or more embodiments corresponding to FIG. 5. The pixel circuit PDC illustrated in FIG. 5 is just one example, and the configuration of the pixel circuit PDC may be modified and implemented.

At least one of the first to seventh transistors T1, T2, T3, T4, T5, T6, and T7 may be a transistor including a low-temperature polycrystalline silicon (LTPS) semiconductor layer. At least one of the first to seventh transistors T1, T2, T3, T4, T5, T6, and T7 may be a transistor including an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

For example, the first transistor T1 that directly affects the brightness of the light-emitting element ED may be configured to include a semiconductor layer made of a polycrystalline silicon having high reliability, thereby achieving a display device having a high resolution. An oxide semiconductor has high carrier mobility and low leakage current, and thus drastic voltage drop does not occur even if a driving time is long. That is, because a drastic color change of an image due to voltage drop does not occur even during low frequency driving, low frequency driving is enabled. As described above, the oxide semiconductor has a low leakage current, and thus may be employed as at least one of the third transistor T3 or the fourth transistor T4, each of which is connected to a gate electrode of the first transistor T1, thereby preventing or reducing leakage current likely to flow to the gate electrode and also reducing power consumption.

Some of the first to seventh transistors T1, T2, T3, T4, T5, T6, and T7 may be p-type transistors, and others may be n-type transistors. For example, the first, second, fifth, sixth, and seventh transistors T1, T2, T5, T6, and T7 may be p-type transistors, and the third and fourth transistors T3 and T4 may be n-type transistors.

The configuration of the pixel circuit PDC according to the present disclosure is not limited to the one or more embodiments corresponding to FIG. 5. The pixel circuit PDC illustrated in FIG. 5 is just one example, and the configuration of the pixel circuit PDC may be modified and implemented. For example, all of the first to seventh transistors T1, T2, T3, T4, T5, T6, and T7 may be either p-type transistors or n-type transistors. Alternatively, the first, second, fifth, and sixth transistors T1, T2, T5, and T6 may be p-type transistors, and the third, fourth, and seventh transistors T3, T4, and T7 may be n-type transistors.

The j-th initialization scan line GILj, the j-th compensation scan line GCLj, the j-th write scan line GWLj, the j-th black scan line GBLj, and the j-th emission control line ECLj may transmit, to the pixel PXij, a j-th initialization scan signal Glj, a j-th compensation scan signal GCj, a j-th write scan line signal GWj, a j-th black scan signal GBj, and a j-th emission control signal EMj, respectively. The i-th data line DLi may transmit an i-th data signal Di to the pixel PXij. The i-th data signal Di may have a voltage level corresponding to an image signal that is input to the display device DD (see FIG. 1).

The first and second drive voltage lines VL1 and VL2 may transmit, to the pixel PXij, a first drive voltage ELVDD and a second drive voltage ELVSS, respectively. In addition, the first and second initialization voltage lines VL3 and VL4 may transmit, to the pixel PXij, a first initialization voltage VINT and a second initialization voltage VAINT, respectively.

The first transistor T1 may be connected between the first drive voltage line VL1, which receives the first drive voltage ELVDD, and the light-emitting element ED. The first transistor T1 may include a first electrode connected to the first drive voltage line VL1 via the fifth transistor T5, a second electrode connected to a pixel electrode (or referred to as an anode) of the light-emitting element ED via the sixth transistor T6, and a third electrode (e.g., gate electrode) connected to one end (e.g., a first node N1) of the first capacitor Cst. The first transistor T1 may receive the i-th data signal Di transmitted by the i-th data line DLi according to a switching operation of the second transistor T2, and then transmit a drive current to the light-emitting element ED.

The second transistor T2 may be connected between the i-th data line DLi and the first electrode of the first transistor T1. The second transistor T2 may include a first electrode connected to the i-th data line DLi, a second electrode connected to the first electrode of the first transistor T1, and a third electrode (e.g., gate electrode) connected to the j-th write scan line GWLj. The second transistor T2 may be turned on in response to the j-th write scan line signal GWj received through the j-th write scan line GWLj, and then transmit the i-th data signal Di received from the i-th data line DLi to the first electrode of the first transistor T1. The second capacitor Cbst may have one end connected to the third electrode of the second transistor T2, and the other end connected to the first node N1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., gate electrode) connected to the j-th compensation scan line GCLj. The third transistor T3 may be turned on in response to the j-th compensation scan signal GCj received through the j-th compensation scan line GCLj, and then connect the third electrode of the first transistor T1 and the second electrode of the first transistor T1 to each other so that the first transistor T1 is diode-connected. The third capacitor Nbst may have one end connected to the third electrode of the third transistor T3, and the other end connected to the first node N1.

The fourth transistor T4 may be connected between the first initialization voltage line VL3, to which the first initialization voltage VINT is applied, and the first node N1. The fourth transistor T4 may include a first electrode connected to the first initialization voltage line VL3, to which the first initialization voltage VINT is transmitted, a second electrode connected to the first node N1, and a third electrode (e.g., gate electrode) connected to the j-th initialization scan line GILj. The fourth transistor T4 may be turned on in response to the j-th initialization scan signal Glj received through the j-th initialization scan line GILj. The turned-on fourth transistor T4 may transmit the first initialization voltage VINT to the first node N1 to initialize a potential of the third electrode (e.g., potential of the first node N1) of the first transistor T1.

The fifth transistor T5 may include a first electrode connected to the first drive voltage line VL1, a second electrode connected to the first electrode of the first transistor T1, and a third electrode (e.g., gate electrode) connected to the j-th emission control line ECLj. The sixth transistor T6 may include a first electrode connected to the second electrode of the first transistor T1, a second electrode connected to the pixel electrode (e.g., a second node N2) of the light-emitting element ED, and a third electrode (e.g., gate electrode) connected to the j-th emission control line ECLj.

The fifth and sixth transistors T5 and T6 may be turned on at substantially the same time in response to the j-th emission control signal EMj received through the j-th emission control line ECLj. The first drive voltage ELVDD applied through the turned-on fifth transistor T5 may be compensated through the diode-connected first transistor T1, and then transmitted to the light-emitting element ED through the sixth transistor T6.

The seventh transistor T7 may include a first electrode connected to the second initialization voltage line VL4, to which the second initialization voltage VAINT is transmitted, a second electrode connected to the second electrode of the sixth transistor T6, and a third electrode (e.g., gate electrode) connected to the j-th black scan line GBLj. The second initialization voltage VAINT may have a voltage level that is less than or equal to that of the first initialization voltage VINT.

The first capacitor Cst may have one end connected to the third electrode of the first transistor T1, and the other end connected to the first drive voltage line VL1. A cathode of the light-emitting element ED may be connected to the second drive voltage line VL2 that transmits the second drive voltage ELVSS. The second drive voltage ELVSS may have a voltage level that is less than that of the first drive voltage ELVDD.

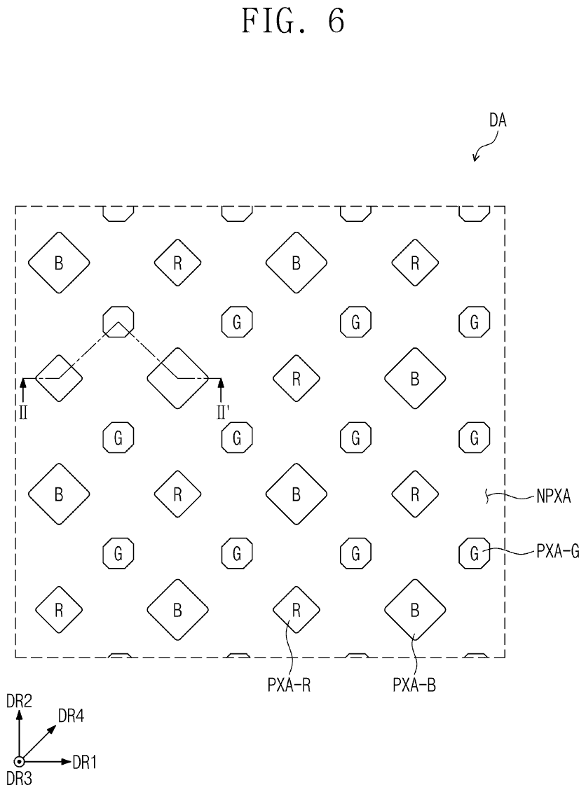

FIG. 6 is an enlarged plan view of a portion of the display area DA of the display panel DP (see FIG. 2) according to one or more embodiments of the present disclosure. FIG. 6 illustrates a plane of the display module DM (see FIG. 3) when viewed on the display surface IS (see FIG. 2) of the display module DM (see FIG. 2), and illustrates arrangement of emission areas PXA-R, PXA-G, and PXA-B.

Referring to FIG. 6, the display area DA may include first to third emission areas PXA-R, PXA-G, and PXA-B, and a peripheral area NPXA surrounding the first to third emission areas PXA-R, PXA-G, and PXA-B. The first to third emission areas PXA-R, PXA-G, and PXA-B may respectively correspond to areas from which light provided from light-emitting elements is emitted. The first to third emission areas PXA-R, PXA-G, and PXA-B may be divided according to colors of light emitted toward the outside of the display module DM (see FIG. 3).

The first to third emission areas PXA-R, PXA-G, and PXA-B may provide light having first to third colors different from each other, respectively. For example, the light having the first color may be red light, the light having the second color may be green light, and the light having the third color may be blue light. However, examples of the light having the first to third colors are not necessarily limited to the foregoing examples.

Each of the first to third emission areas PXA-R, PXA-G, and PXA-B may be defined as an area in which a top surface of an anode is exposed by an emission-opening portion to be described later. The peripheral area NPXA may set a boundary of each of the first to third emission areas PXA-R, PXA-G, and PXA-B, and prevent or reduce mixture of colors between the first to third emission areas PXA-R, PXA-G, and PXA-B.

Each of the first to third emission areas PXA-R, PXA-G, and PXA-B may be provided in plurality to have a preset arrangement shape, and may be repeatedly arranged in the display area DA. For example, the first and third emission areas PXA-R and PXA-B may be alternately arranged in the first direction DR1 and constitute a “first group”. The second emission areas PXA-G may be arranged in the first direction DR1 and constitute a “second group”. Each of the “first group” and the “second group” may be provided in plurality, and the “first groups” and the “second groups” may be alternately arranged in the second direction DR2.

One second emission area PXA-G may be spaced apart from one first emission area PXA-R or one third emission area PXA-B in a fourth direction DR4. The fourth direction DR4 may be defined as a direction between the first and second directions DR1 and DR2.

The arrangement shape of the first to third emission areas PXA-R, PXA-G, and PXA-B illustrated in FIG. 6 is an example and is not limited thereto. The first to third emission areas PXA-R, PXA-G, and PXA-B may be arranged in various shapes. In one or more embodiments, the first to third emission areas PXA-R, PXA-G, and PXA-B may have a PENTILE® arrangement shape as illustrated in FIG. 6. Alternatively, the first to third emission areas PXA-R, PXA-G, and PXA-B may have a stripe arrangement shape or a diamond (Diamond Pixel™) arrangement shape (PENTILE® and Diamond Pixel™ being registered trademarks of Samsung Display Co., Ltd., Republic of Korea).

Each of the first to third emission areas PXA-R, PXA-G, and PXA-B may have various shapes on a plane. For example, each of the first to third emission areas PXA-R, PXA-G, and PXA-B may have a shape, such as a polygonal, circular, or oval shape. As an example, FIG. 6 illustrates the first and third emission areas PXA-R and PXA-B each having a square (or rhombus) shape and the second emission area PXA-G having an octagonal shape on a plane.

The first to third emission areas PXA-R, PXA-G, and/or PXA-B may have substantially the same shape, or at least one thereof may have a different shape on a plane. As an example, FIG. 6 illustrates the first and third emission areas PXA-R and PXA-B having the same shape, and the second emission area PXA-G having a different shape from the first and third emission areas PXA-R and PXA-B on a plane.

At least some of the first to third emission areas PXA-R, PXA-G, and PXA-B may have different areas on a plane. In one or more embodiments, the area of the first emission area PXA-R that emits the red light may be greater than the area of the second emission area PXA-G that emits the green light, and may be less than the area of the third emission area PXA-B that emits the blue light. However, the large-small relationship of the areas of the first to third emission areas PXA-R, PXA-G, and PXA-B according to the colors of the emitted light is not limited thereto, and may vary according to the design of the display module DM (see FIG. 3). However, the present disclosure is not limited thereto, and the respective areas of the first to third emission areas PXA-R, PXA-G, and PXA-B may be the same on a plane/in plan view.

The shape, area, arrangement, or the like of the first to third emission areas PXA-R, PXA-G, and PXA-B of the display module DM (see FIG. 3) according to one or more embodiments of the present disclosure may be variously designed according to the color of the emitted light or the size or configuration of the display module DM (see FIG. 2), and are not limited to the one or more embodiments corresponding to FIG. 6.

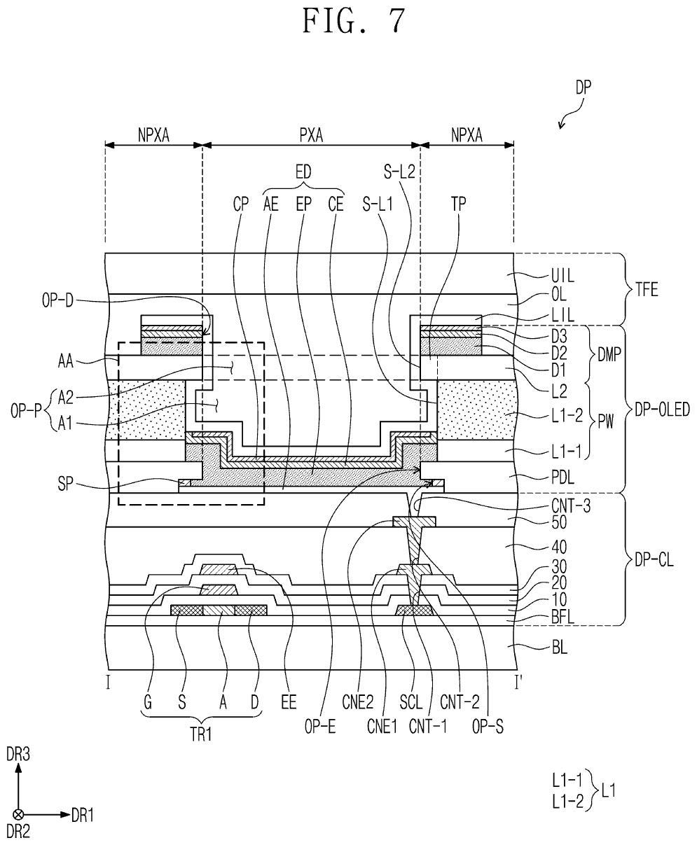

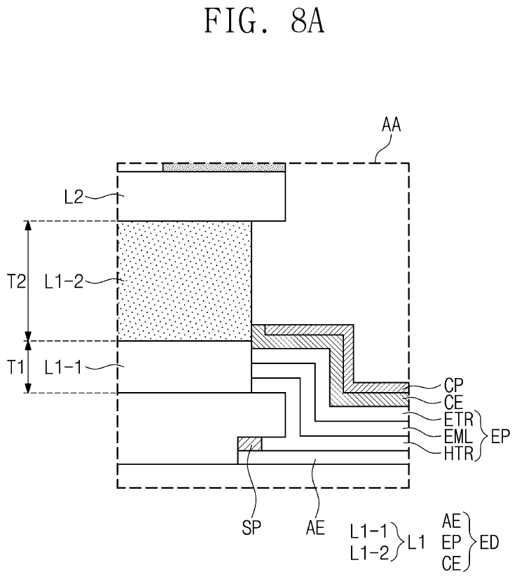

FIG. 7 is a cross-sectional view of the display panel according to one or more embodiments of the present disclosure taken along the line I-I′ in FIG. 4. FIGS. 8A and 8B are each an enlarged view illustrating area AA in FIG. 7. In the description with reference to FIGS. 7, 8A and 8B, redundant description of components denoted as the same/similar reference numbers or symbols as/to those described with reference to FIG. 4 will be omitted.

FIG. 7 illustrates an enlarged view of one emission area PXA in the display area DA (see FIG. 6), and the emission area PXA in FIG. 7 may correspond to any one of the first to third emission areas PXA-R, PXA-G and PXA-B in FIG. 6. Referring to FIG. 7, the display panel DP may include a base layer BL, a circuit element layer DP-CL, a display element layer DP-OLED, and a thin film encapsulation layer TFE.

The display panel DP may include a plurality of insulation layers, a semiconductor pattern, a conductive pattern, a signal line, and so on. The insulation layers, a semiconductor layer, and a conductive layer are formed through coating, deposition, or the like. Thereafter, the insulation layers, the semiconductor layer, and the conductive layer may be selectively patterned by performing a photolithography process and an etching process. The semiconductor pattern, the conductive pattern, and the signal line, and the like, which are included in the circuit element layer DP-CL or the display element layer DP-OLED, may be formed through those processes.

The circuit element layer DP-CL may be located on the base layer BL. The circuit element layer DP-CL may include a buffer layer BFL, a transistor TR1, a signal transmission region SCL, first to fifth insulation layers 10, 20, 30, 40, and 50, an upper electrode EE, and a plurality of connection electrodes CNE1 and CNE2.

The buffer layer BFL may be located on the base layer BL. The buffer layer BFL may improve bonding force between the base layer BL and the semiconductor pattern. The buffer layer BFL may include a silicon oxide layer and a silicon nitride layer. The silicon oxide layer and the silicon nitride layer may be stacked alternately.

The semiconductor pattern may be located on the buffer layer BFL. The semiconductor pattern may include polysilicon. However, the present disclosure is not limited thereto, and the semiconductor pattern may also include amorphous silicon or a metal oxide. FIG. 7 illustrates only a portion of the semiconductor pattern, and the semiconductor pattern may be further located in the plurality of emission areas PXA-R, PXA-G, and PXA-B (see FIG. 6). The semiconductor pattern may be arranged over the plurality of emission areas PXA-R, PXA-G, and PXA-B (see FIG. 6) according to a specific rule. The semiconductor pattern may have different electrical properties according to whether or not the semiconductor pattern is doped. The semiconductor pattern may include a first region having a high doping concentration and a second region having a low doping concentration. The first region may be doped with an n-type dopant or a p-type dopant. A p-type transistor may include the first region doped with the p-type dopant.

The first region may have higher conductivity than the second region, and substantially serve as an electrode or a signal line. The second region may substantially correspond to an active (or channel) of a transistor. For example, a portion of the semiconductor pattern may be an active of a transistor, another portion may be a source or a drain of the transistor, and still another portion may be a conductive region.

A source S, an active A, and a drain D of the transistor TR1 may be formed from the semiconductor pattern. FIG. 7 illustrates a portion of the signal transmission region SCL formed from the semiconductor pattern. The signal transmission region SCL may be connected to the drain D of the transistor TR1 on a plane.

The first to fifth insulation layers 10, 20, 30, 40, and 50 may be located on the buffer layer BFL. Each of the first to fifth insulation layers 10, 20, 30, 40, and 50 may be an inorganic layer or an organic layer.

The first insulation layer 10 may be located on (e.g., above) the buffer layer BFL. The first insulation layer 10 may cover the source S, the active A, and the drain D of the transistor TR1, and the signal transmission region SCL, which are located on buffer layer BFL. A gate G of the transistor TR1 may be located on the first insulation layer 10. The second insulation layer 20 may be located on the first insulation layer 10 to cover the gate G. The upper electrode EE may be located on the second insulation layer 20. The third insulation layer 30 may be located on the second insulation layer 20 to cover the upper electrode EE.

A first connection electrode CNE1 may be located on the third insulation layer 30. The first connection electrode CNE1 may be connected to the signal transmission region SCL through a contact hole CNT-1 passing through the first to third insulation layers 10, 20, and 30. The fourth insulation layer 40 may be located on the third insulation layer 30 to cover the first connection electrode CNE1. The fourth insulation layer 40 may be an organic layer.

A second connection electrode CNE2 may be located on the fourth insulation layer 40. The second connection electrode CNE2 may be connected to the first connection electrode CNE1 through a contact hole CNT-2 passing through the fourth insulation layer 40. The fifth insulation layer 50 may be located on the fourth insulation layer 40 to cover the second connection electrode CNE2. The fifth insulation layer 50 may be an organic layer.

The display element layer DP-OLED may be located on the circuit element layer DP-CL. The display element layer DP-OLED may include a light-emitting element ED, a sacrificial pattern SP, a pixel-defining film PDL, a partition wall PW, and dummy patterns DMP.

The light-emitting element ED may include an anode AE (or first electrode), an emission pattern EP, and a cathode CE (or second electrode).

The anode AE may be located on the fifth insulation layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 passing through and defined in the fifth insulation layer 50. Thus, the anode AE may be electrically connected to the signal transmission region SCL through the first and second connection electrodes CNE1 and CNE2, and may be electrically connected to a corresponding circuit element. The anode AE may have a single-layer structure or a multilayer structure. The anode AE may include a plurality of layers including an indium tin oxide (ITO) or Ag. For example, the anode AE may include a layer including ITO (hereinafter referred to as a lower ITO layer), a layer located on the lower ITO layer and including Ag (hereinafter referred to as an Ag layer), and a layer located on the Ag layer and including ITO (hereinafter referred to as an upper ITO layer).

The sacrificial pattern SP may be positioned between the anode AE and the pixel-defining film PDL. A sacrificial-opening portion OP-S that exposes a portion of a top surface of the anode AE may be defined in the sacrificial pattern SP. The sacrificial-opening portion OP-S may overlap an emission-opening portion OP-E to be described later on a plane.

The pixel-defining film PDL may be located on the base layer BL. For example, the pixel-defining film PDL may be located on the fifth insulation layer 50 of the circuit element layer DP-CL. The emission-opening portion OP-E may be defined in the pixel-defining film PDL. The emission-opening portion OP-E may correspond to the anode AE, and the pixel-defining film PDL may expose at least a portion of the anode AE through the emission-opening portion OP-E.

In addition, the emission-opening portion OP-E may correspond to the sacrificial-opening portion OP-S of the sacrificial pattern SP. According to one or more embodiments of the present disclosure, the top surface of the anode AE may be spaced apart from the pixel-defining film PDL with the sacrificial pattern SP therebetween on a cross-sectional view, and accordingly, the anode AE may be protected from being damaged in a process of forming the emission-opening portion OP-E.

The area of the emission-opening portion OP-E may be less than the area of the sacrificial-opening portion OP-S on a plane. That is, an inner side surface of the pixel-defining film PDL, which defines the emission-opening portion OP-E, may be closer a center of the anode AE than an inner side surface of the sacrificial pattern SP, which defines the sacrificial-opening portion OP-S. However, the present disclosure is not limited thereto, and the inner side surface of the sacrificial pattern SP, which defines the sacrificial-opening portion OP-S, may be substantially aligned with the inner side surface of the pixel-defining film PDL, which defines the emission-opening portion OP-E.

The pixel-defining film PDL may include an inorganic insulation material. The pixel-defining film PDL may include at least one of a silicon oxide (SiOₓ), a silicon nitride (SiNₓ), or a silicon oxynitride (SiOₓN_{y}). For example, the pixel-defining film PDL may include a silicon nitride (SiNₓ). The pixel-defining film PDL may be positioned between the anode AE and the partition wall PW and block an electrical connection between the anode AE and the partition wall PW.

The partition wall PW may be located on the pixel-defining film PDL. A partition-wall-opening portion OP-P may be defined in the partition wall PW. The partition-wall-opening portion OP-P may overlap the emission-opening portion OP-E, and may expose at least a portion of the anode AE.

The partition wall PW may have an undercut shape on a cross-sectional view. The partition wall PW may include a plurality of layers stacked in sequence, and at least one of the plurality of layers may be recessed from the other layers. Accordingly, the partition wall PW may include a tip portion TP.

The partition wall PW may include a first partition wall layer L1 and a second partition wall layer L2. The first partition wall layer L1 may be located on the pixel-defining film PDL, and the second partition wall layer L2 may be located on the first partition wall layer L1. As illustrated in FIG. 7, a thickness of the first partition wall layer L1 may be greater than a thickness of the second partition wall layer L2, but is not limited thereto.

The first partition wall layer L1 may be relatively recessed from the emission area PXA compared to the second partition wall layer L2. The first partition wall layer L1 may be undercut relative to the second partition wall layer L2. A portion of the second partition wall layer L2, which protrudes from the first partition wall layer L1 toward the emission area PXA, may be defined as the tip portion TP in the partition wall PW. That is, the second partition wall layer L2 may include the tip portion TP protruding from the first partition wall layer L1 toward the partition-wall-opening portion OP-P. The tip portion TP of the second partition wall layer L2 may not overlap the first partition wall layer L1 on a plane (e.g., an edge of the second partition wall layer L2/tip portion TP might not be aligned with an edge of the first partition wall layer L1).

The first partition wall layer L1 may include a lower partition wall layer L1-1 and an upper partition wall layer L1-2. The lower partition wall layer L1-1 may be located on the pixel-defining film PDL, and the upper partition wall layer L1-2 may be located on the lower partition wall layer L1-1. The lower partition wall layer L1-1 may be located directly on the pixel-defining film PDL, and the upper partition wall layer L1-2 may be located directly on the lower partition wall layer L1-1. Thus, the lower partition wall layer L1-1 may have a bottom surface that is contacting a top surface of the pixel-defining film PDL, and a top surface that is contacting a bottom surface of the upper partition wall layer L1-2. The upper partition wall layer L1-2 may have a top surface that is contacting a bottom surface of the second partition wall layer L2.

The lower partition wall layer L1-1 may be a high-resistance layer that is not substantially electrically conductive. The lower partition wall layer L1-1 may include an insulation material. The lower partition wall layer L1-1 may include amorphous silicon (a-Si) as an insulation material. For example, the lower partition wall layer L1-1 may be made of amorphous silicon (a-Si).

The upper partition wall layer L1-2 may include an electrically conductive layer. The upper partition wall layer L1-2 may include a conductive material. The upper partition wall layer L1-2 may include n⁺ silicon (n⁺ Si) as a conductive material. For example, the upper partition wall layer L1-2 may be made of n⁺ silicon (n⁺ Si).

Referring to FIGS. 8A and 8B, the lower partition wall layer L1-1 may have a first thickness T1, and the upper partition wall layer L1-2 may have a second thickness T2. The first thickness T1 may be less than the second thickness T2. The first thickness T1 may be less than about 0.5 times the sum of the first thickness T1 and the second thickness T2. That is, the lower partition wall layer L1-1 may have a small thickness that is less than about 0.5 times that of the first partition wall layer L1. For example, the first thickness T1 may be about 200 angstroms (Å), and the second thickness T2 may be about 4000 angstroms (Å). However, one or more embodiments is not limited thereto. A ratio of the first thickness T1 to the second thickness T2 may be adjusted according to the structure of the light-emitting element ED.

Referring to FIG. 7 again, the partition-wall-opening portion OP-P defined in the partition wall PW may include a first region A1 and a second region A2. The first partition wall layer L1 may have a first inner side surface S-L1 that defines the first region A1 of the partition-wall-opening portion OP-P. The lower partition wall layer L1-1 and the upper partition wall layer L1-2, which constitute the first partition wall layer L1, may share the first region A1 and the first inner side surface S-L1 that defines the first region A1. The lower partition wall layer L1-1 and the upper partition wall layer L1-2 may include substantially the same composition of amorphous silicon (a-Si) and n⁺ silicon (n⁺ Si), and may be etched at substantially the same time in a manufacturing process to be described later, so that the lower partition wall layer L1-1 and the upper partition wall layer L1-2 are substantially uniformly undercut relative to the second partition wall layer L2. Thus, the inner side surface of the lower partition wall layer L1-1 and the inner side surface of the upper partition wall layer L1-2, each of which defines the first region A1, may be aligned with each other in the third direction DR3.

The second partition wall layer L2 may have a second inner side surface S-L2 that defines the second region A2. The second inner side surface S-L2 of the second partition wall layer L2 may be closer to the center of the anode AE than the first inner side surface S-L1 of the first partition wall layer L1 on a cross-sectional view. The first inner side surface S-L1 may be recessed from the second inner side surface S-L2 in a direction that is away from the center of the anode AE.

The first region A1 may have a width that is different from a width of the second region A2 in the first direction DR1. The width of the first region A1 may be greater than the width of the second region A2 in the first direction DR1. In this case, the second region A2 of the partition-wall-opening portion OP-P may be an area that defines the tip portion TP. Here, the emission area PXA may be considered an area of the anode AE, which is exposed from the second region A2 of the partition wall PW that corresponds thereto.

The second partition wall layer L2 may include a conductive material. For example, the conductive material may include a metal, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide. In one or more embodiments, the second partition wall layer L2 may include at least one of molybdenum (Mo) or titanium (Ti).

As an example, FIG. 7 illustrates the first inner side surface S-L1 and the second inner side surface S-L2, each of which is substantially perpendicular to the top surface of the pixel-defining film PDL, but the present disclosure is not limited thereto. For example, the partition wall PW may have a tapered shape or a reverse tapered shape.

The emission pattern EP may be located on the anode AE. The emission pattern EP may include at least one emission layer EML (see FIG. 8A) including a light-emitting material. For example, the emission pattern EP may include one emission layer EML (see FIG. 8A), and may include a hole transport region HTR (see FIG. 8A) and an electron transport region ETR (see FIG. 8A) that are positioned with the emission layer EML (see FIG. 8A) therebetween. In addition, the emission pattern EP may include a plurality of emission structures provided to be stacked in sequence on the anode AE in a thickness direction. Each of the plurality of emission structures may include the hole transport region HTR (see FIG. 8A) and the electron transport region ETR (see FIG. 8A) that are positioned with the emission layer EML (see FIG. 8A) therebetween. That is, the light-emitting element ED including the emission pattern EP according to one or more embodiments may have a structure including one emission layer EML (see FIG. 8A), or have a tandem structure including a plurality of emission layers EML. The emission pattern EP may be referred to as an “intermediate layer”.

The emission pattern EP may be patterned by the tip portion TP defined in the partition wall PW. The emission pattern EP may be located inside the sacrificial-opening portion OP-S, the emission-opening portion OP-E, and the partition-wall-opening portion OP-P (e.g., inside in a plan view). The emission pattern EP may be deposited on a portion of the top surface of the pixel-defining film PDL, which is exposed from the partition-wall-opening portion OP-P. That is, the emission pattern EP may have both ends, each of which is provided on the top surface of the pixel-defining film PDL.

The emission pattern EP may contact the lower partition wall layer L1-1, and may not contact the upper partition wall layer L1-2. The emission pattern EP may include at least one organic layer including a charge generation material. The charge generation material may be dispersed uniformly or non-uniformly in the organic layer. The charge generation material may be, for example, a p-type dopant. The emission pattern EP may include at least one organic layer doped with a p-type dopant. The p-type dopant may include at least one of a metal halide compound, a quinone derivative, a metal oxide, or a cyano group-containing compound, but is not limited thereto. For example, the p-type dopant may include a metal halide compound, such as Cul or Rbl, a quinone derivative, such as Tetracyanoquinodimethane (TCNQ) or 2,3,5,6-tetrafluoro-7,7,8,8-tetracyanoquinodimethane (F4-TCNQ), a metal oxide, such as a tungsten oxide or a molybdenum oxide, or a cyano group-containing compound, such as dipyrazino[2,3-f:2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9). However, one or more embodiments is not limited thereto.

The organic layer doped with the p-type dopant may have conductivity. If the emission pattern EP including the organic layer doped with the p-type dopant contacts the upper partition wall layer L1-2 including a conductive material, then the upper partition wall layer L1-2 and the emission pattern EP may be electrically connected to each other to generate leakage current. According to one or more embodiments of the present disclosure, as the emission pattern EP is not contacting (e.g., is separated from, or is spaced apart from) the upper partition wall layer L1-2 and contacts the lower partition wall layer L1-1, the leakage current may be reduced or prevented from being generated. For example, according to one or more embodiments of the present disclosure, the lower partition wall layer L1-1 that is contacting the emission pattern EP may be made of an insulation material, such as amorphous silicon (a-Si), thereby reducing or preventing the leakage current from being generated even if a portion of the emission pattern EP (e.g., hole injection layer and/or charge generation layer, each of which is doped with a p-type dopant) has conductivity.

The cathode CE may be located on the emission pattern EP. The cathode CE may be patterned by the tip portion TP defined in the partition wall PW. At least a portion of the cathode CE may be located in the partition-wall-opening portion OP-P. The cathode CE may be deposited on a portion of the top surface of the pixel-defining film PDL, which is exposed from the partition-wall-opening portion OP-P. That is, the cathode CE may have both ends, each of which is provided on the pixel-defining film PDL. The cathode CE may contact the first inner side surface S-L1 of the first partition wall layer L1. For example, at least a portion of the end of the cathode CE may contact the inner side surface of the lower partition wall layer L1-1, and an end of the cathode CE, which is not contacting the lower partition wall layer L1-1, may contact the inner side surface of the upper partition wall layer L1-2. Alternatively, the entire end of the cathode CE may contact the inner side surface of the upper partition wall layer L1-2.

The cathode CE may have conductivity. The cathode CE may be made of various materials, such as a metal, a transparent conductive oxide (TCO), or a conductive polymeric material, as long as the cathode CE is capable of exhibiting conductivity. For example, the cathode CE may include silver (Ag), magnesium (Mg), lead (Pb), copper (Cu), or a compound thereof.

The display element layer DP-OLED may further include a capping pattern CP. The capping pattern CP may be located in the partition-wall-opening portion OP-P. The capping pattern CP may be located on the cathode CE. The capping pattern CP may be patterned by the tip portion TP defined in the partition wall PW.

The dummy patterns DMP may be located on (e.g., above) the partition wall PW. The dummy patterns DMP may include a first dummy pattern D1, a second dummy pattern D2, and a third dummy pattern D3. Thus, the first to third dummy patterns D1, D2, and D3 may be stacked in sequence on a top surface of the second partition wall layer L2 of the partition wall PW in the third direction DR3.

The first dummy pattern D1 may include an organic material. For example, the first dummy pattern D1 may include the same material as the emission pattern EP. The first dummy pattern D1 may be formed together with the emission pattern EP at substantially the same time through one process, and then separated from the emission pattern EP by the undercut shape of the partition wall PW.

The second dummy pattern D2 may include a conductive material. For example, the second dummy pattern D2 may include the same material as the cathode CE. The second dummy pattern D2 may be formed together with the cathode CE at substantially the same time through one process, and then separated from the cathode CE by the undercut shape of the partition wall PW.

The third dummy pattern D3 may include a conductive material. For example, the third dummy pattern D3 may include the same material as the capping pattern CP. The third dummy pattern D3 may be formed together with the capping pattern CP at substantially the same time through one process, and then separated from the capping pattern CP by the undercut shape of the partition wall PW.

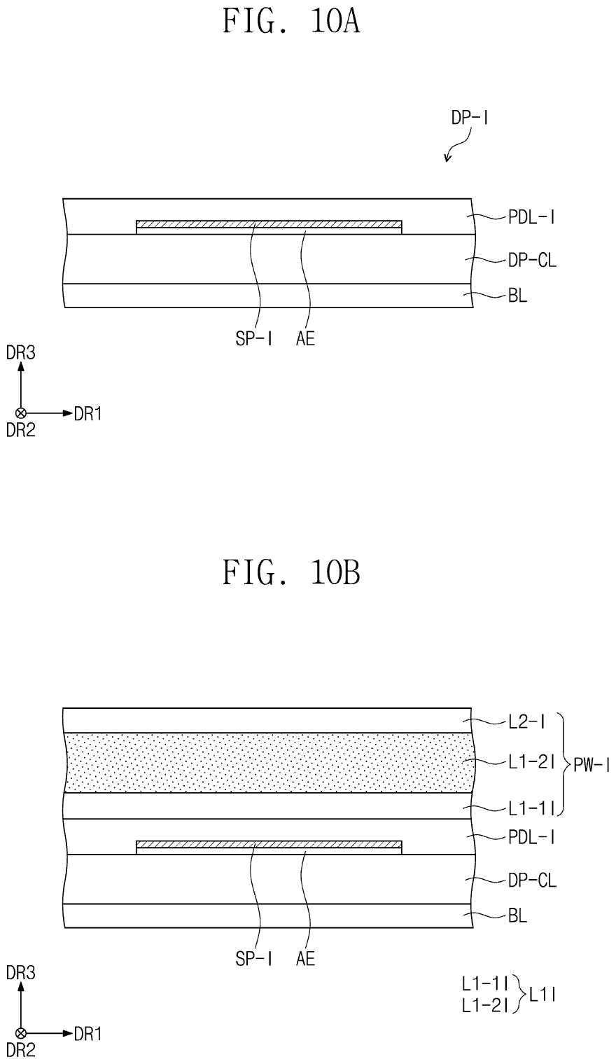

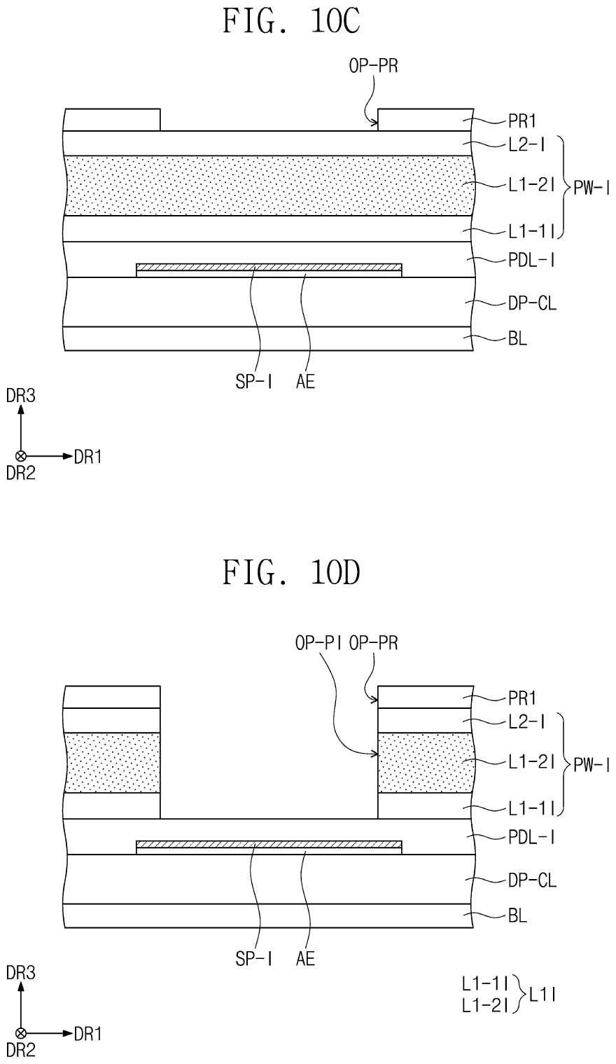

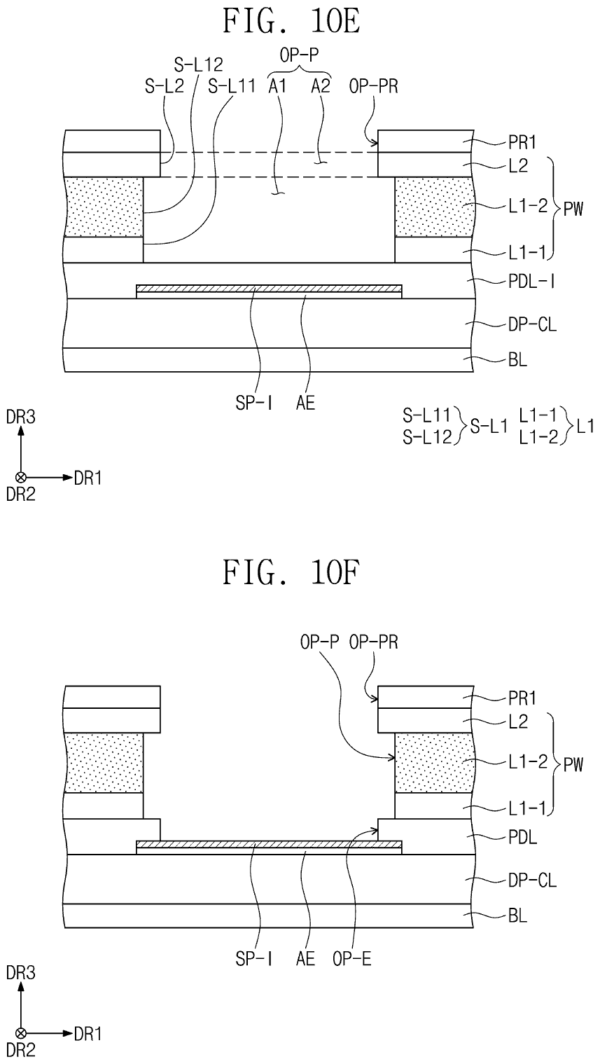

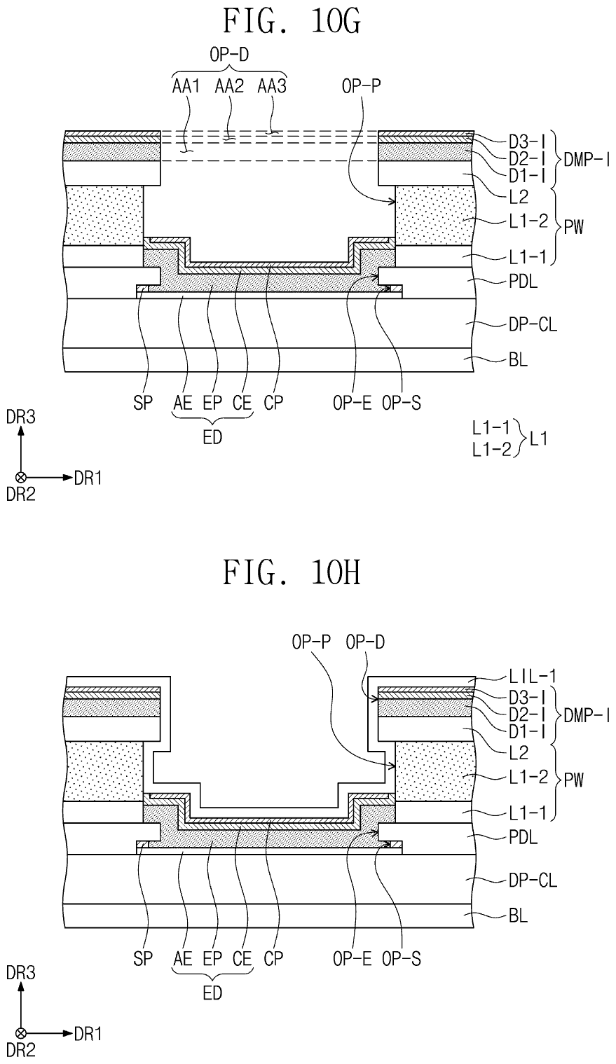

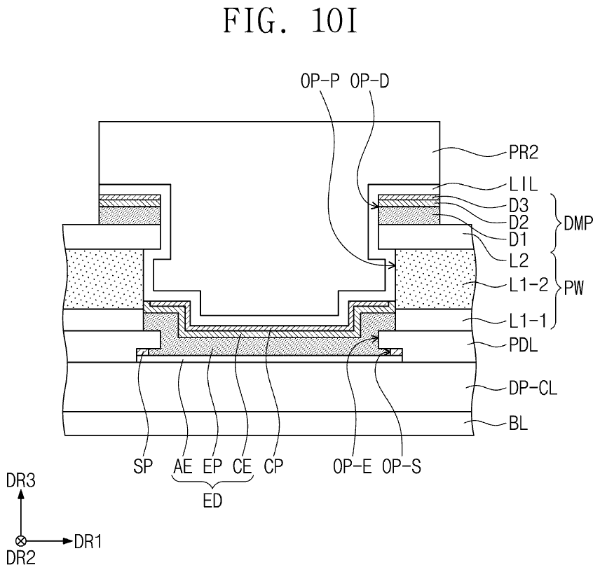

A dummy opening portion OP-D may be defined in the dummy patterns DMP. The dummy opening portion OP-D may overlap the emission-opening portion OP-E on a plane. The dummy opening portion OP-D may include first to third regions arranged in sequence in the third direction DR3. In the dummy opening portion OP-D, a first region AA1 (see FIG. 10G) may be defined by an inner side surface of the first dummy pattern D1, a second region AA2 (see FIG. 10G) may be defined by an inner side surface of the second dummy pattern D2, and a third region AA3 (see FIG. 10G) may be defined by an inner side surface of the third dummy pattern D3. Each of the first to third dummy patterns D1, D2, and D3 may have a closed line shape surrounding the emission area PXA on a plane.

As an example, FIG. 7 illustrates the respective inner side surfaces of the first to third dummy patterns D1, D2, and D3, which are aligned with the second inner side surface S-L2 of the second partition wall layer L2. However, the present disclosure is not limited thereto, and the first to third dummy patterns D1, D2, and D3 may cover at least a portion of the second inner side surface S-L2 of the second partition wall layer L2.

The thin film encapsulation layer TFE may be located on the display element layer DP-OLED. The thin film encapsulation layer TFE may include a lower inorganic encapsulation pattern LIL, an organic encapsulation film OL, and an upper inorganic encapsulation film UIL.

The lower inorganic encapsulation pattern LIL may be located on the light-emitting element ED and the capping pattern CP. The lower inorganic encapsulation pattern LIL may correspond to the emission-opening portion OP-E. The lower inorganic encapsulation pattern LIL may cover the light-emitting element ED, the capping pattern CP, and the dummy patterns DMP, and have a portion located inside the partition-wall-opening portion OP-P. According to one or more embodiments, the lower inorganic encapsulation pattern LIL may contact each of the first inner side surface S-L1 of the first partition wall layer L1 and the second inner side surface S-L2 of the second partition wall layer L2. For example, the lower inorganic encapsulation pattern LIL may contact each of an inner side surface S-L12 (see FIG. 10E) of the upper partition wall layer L1-2 and the second inner side surface S-L2 of the second partition wall layer L2.

In one or more embodiments, the lower inorganic encapsulation pattern LIL may include an inorganic material. For example, the lower inorganic encapsulation pattern LIL may include a silicon nitride (SiNₓ). Accordingly, the lower inorganic encapsulation pattern LIL may exhibit suitable adhesion with each of the lower partition wall layer L1-1 including amorphous silicon (a-Si) and the upper partition wall layer L1-2 including n⁺ silicon (n⁺ Si). The lower inorganic encapsulation pattern LIL including a silicon nitride (SiNₓ) may be very resistant to moisture due to suitable interface bonding force with the first partition wall layer L1.

The organic encapsulation film OL may cover the lower inorganic encapsulation pattern LIL, and may provide a flat top surface. The upper inorganic encapsulation film UIL may be located on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from a foreign matter, such as dust particles.

FIGS. 8A and 8B each illustrate a structure of the light-emitting element ED illustrated in FIG. 7. FIG. 8A illustrates an example of an emission pattern EP including one emission layer EML in the light-emitting element ED according to one or more embodiments. FIG. 8B illustrates an example of an emission pattern EP including a plurality of emission layers EML in the light-emitting element ED according to one or more embodiments.

Referring to FIG. 8A, an emission pattern EP may include an emission layer EML including one light-emitting material. The emission pattern EP may include a hole transport region HTR positioned between an anode AE and the emission layer EML, and may include an electron transport region ETR positioned between the emission layer EML and a cathode CE.

The hole transport region HTR may include at least one of a hole injection layer, a hole transport layer, an emission-auxiliary layer, or an electron-blocking layer. For example, the hole transport region HTR may include the hole injection layer and the hole transport layer, which are stacked in sequence on the anode AE.

The hole transport region HTR may include a p-type dopant as a charge generation material. At least one of the hole injection layer, the hole transport layer, the emission-auxiliary layer, or the electron-blocking layer may include a p-type dopant. For example, the hole transport region HTR may include the hole injection layer including a p-type dopant. The hole injection layer may correspond to the foregoing organic layer doped with the p-type dopant, but is not limited thereto.

The electron transport region ETR may include at least one of a hole-blocking layer, an electron transport layer, or an electron injection layer. For example, the electron transport region ETR may include the electron transport layer and the electron injection layer, which are located on the emission layer EML, but one or more embodiments is not limited thereto. The electron transport region ETR may include a single layer made of a single material, or a single layer made of a plurality of different materials, or may have a multilayer structure including a plurality of layers made of a plurality of different materials.

Referring to FIG. 8B, an emission pattern EP according to one or more embodiments may include a plurality of emission structures EG1 and EG2. Each of the plurality of emission structures EG1 and EG2 may include an emission layer EML. Accordingly, the emission pattern EP may include a plurality of emission layers EML. That is, the light-emitting element ED according to one or more embodiments may be a light-emitting element having a tandem structure including a plurality of emission layers EML.

A charge generation layer CGL may be positioned between the plurality of emission structures EG1 and EG2. The charge generation layer CGL may include a p-type dopant as a charge generation material. The charge generation layer CGL may correspond to the foregoing organic layer doped with the p-type dopant. The contents described with reference to FIG. 8A may similarly apply to the p-type dopant.

In the light-emitting element ED illustrated in FIG. 8B, the emission pattern EP may include two emission structures EG1 and EG2. However, one or more embodiments is not limited thereto, and the emission pattern EP may include three or four emission structures.

The emission pattern EP according to one or more embodiments may include a first emission structure EG1 and a second emission structure EG2, which are stacked in sequence in a thickness direction between an anode AE and a cathode CE that face each other. The first emission structure EG1 may be located on the anode AE, and the second emission structure EG2 may be located on the charge generation layer CGL. That is, the light-emitting element ED according to one or more embodiments may include the anode AE, the first emission structure EG1, the charge generation layer CGL, the second emission structure EG2, and the cathode CE that are stacked in sequence.

Each of the first emission structure EG1 and the second emission structure EG2 may include a hole transport region HTR, an emission layer EML, and an electron transport region ETR. In each of the first emission structure EG1 and the second emission structure EG2, the hole transport region HTR and the electron transport region ETR may be positioned with the emission layer EML therebetween. In the first emission structure EG1, the hole transport region HTR may be closer to the anode AE than the electron transport region ETR. In the second emission structure EG2, the electron transport region ETR may be closer to the cathode CE than the hole transport region HTR.

At least one of the hole transport region HTR or the charge generation layer CGL, which is included in each of the first and second emission structures EG1 and EG2, may include an organic layer doped with a p-type dopant, but one or more embodiments is not limited thereto.

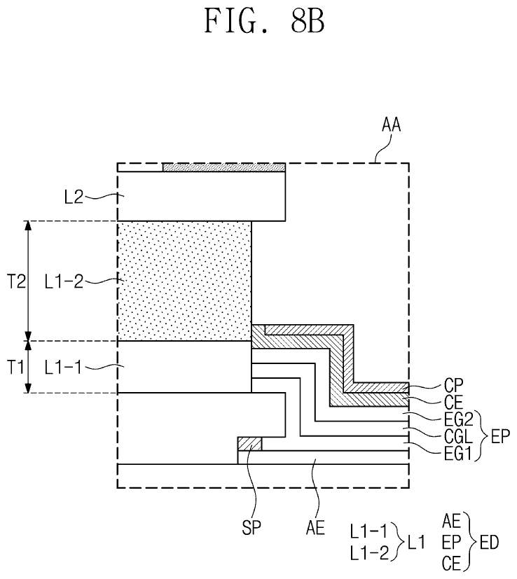

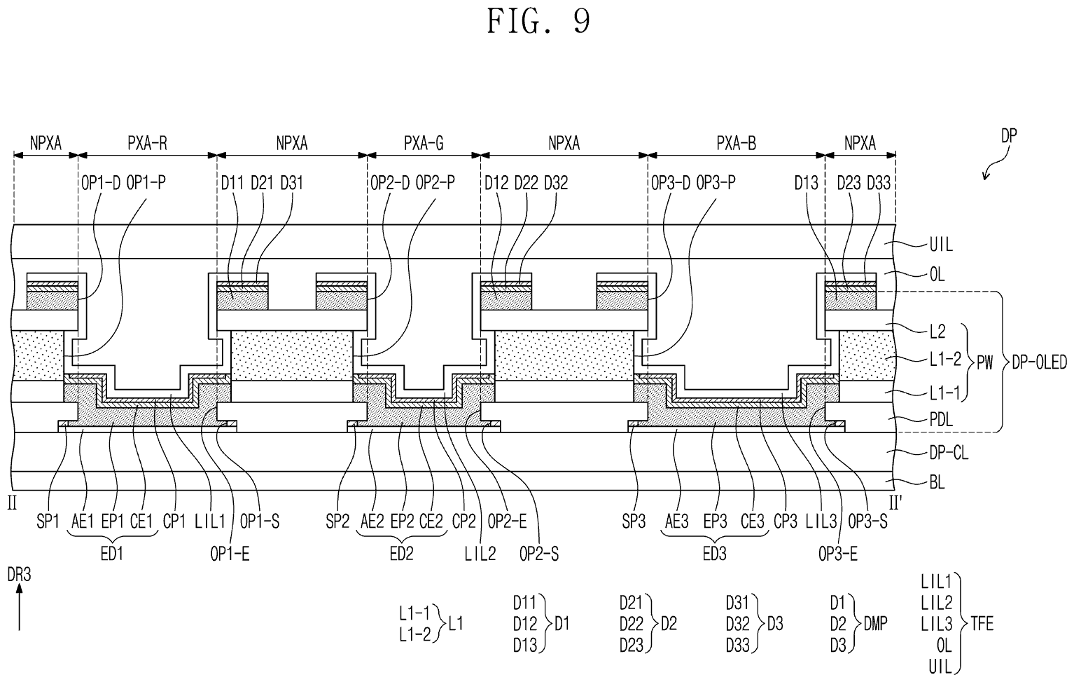

FIG. 9 is a cross-sectional view taken along the line II-II′ in FIG. 6. FIG. 9 is an enlarged view of one first emission area PXA-R, one second emission area PXA-G, and one third emission area PXA-B. The description of one emission area PXA in FIG. 7 may similarly apply to each of the first to third emission areas PXA-R, PXA-G and PXA-B.

Referring to FIG. 9, the display panel DP according to one or more embodiments may include a base layer BL, a circuit element layer DP-CL, a display element layer DP-OLED, and a thin film encapsulation layer TFE. The display element layer DP-OLED may include light-emitting elements ED1, ED2, and ED3, sacrificial patterns SP1, SP2, and SP3, a pixel-defining film PDL, a partition wall PW, and dummy patterns DMP.

The light-emitting elements ED1, ED2, and ED3 may include a first light-emitting element ED1, a second light-emitting element ED2, and a third light-emitting element ED3. The first light-emitting element ED1 may include a first anode AE1, a first emission pattern EP1, and a first cathode CE1. The second light-emitting element ED2 may include a second anode AE2, a second emission pattern EP2, and a second cathode CE2. The third light-emitting element ED3 may include a third anode AE3, a third emission pattern EP3, and a third cathode CE3. The first to third anodes AE1, AE2, and AE3 may be provided as a plurality of patterns. In one or more embodiments, the first emission pattern EP1 may provide red light, the second emission pattern EP2 may provide green light, and the third emission pattern EP3 may provide blue light.

First to third emission-opening portions OP1-E, OP2-E, and OP3-E may be defined in the pixel-defining film PDL. The first emission-opening portion OP1-E may expose at least a portion of the first anode AE1. The second emission-opening portion OP2-E may expose at least a portion of the second anode AE2. The third emission-opening portion OP3-E may expose at least a portion of the third anode AE3.

The sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be located on top surfaces on the first to third anodes AE1, AE2, and AE3, respectively. First to third sacrificial-opening portions OP1-S, OP2-S, and OP3-S overlapping the first to third emission-opening portions OP1-E, OP2-E and OP3-E may be defined in the first to third sacrificial patterns SP1, SP2, and SP3, respectively.

In one or more embodiments, first to third partition-wall-opening portions OP1-P, OP2-P, and OP3-P overlapping the first to third emission-opening portions OP1-E, OP2-E, and OP3-E, respectively, may be defined in the partition wall PW. The first emission area PXA-R may be defined as an area, which is exposed by the first partition-wall-opening portion OP1-P, of the top surface of the first anode AE1. The second emission area PXA-G may be defined as an area, which is exposed by the second partition-wall-opening portion OP2-P, of the top surface of the second anode AE2. The third emission area PXA-B may be defined as an area, which is exposed by the third partition-wall-opening portion OP3-P, of the top surface of the third anode AE3.

Each of the first to third partition-wall-opening portions OP1-P, OP2-P, and OP3-P may include the first region A1 (see FIG. 7) and the second region A2 (see FIG. 7), which are described with reference to FIG. 7. A first partition wall layer L1 may have the first inner side surfaces S-L1 (see FIG. 7) that define the first regions A1 (see FIG. 7) of the first to third partition-wall-opening portions OP1-P, OP2-P, and OP3-P, respectively, and a second partition wall layer L2 may have the second inner side surfaces S-L2 (see FIG. 7) that define the second regions A2 (see FIG. 7) of the first to third partition-wall-opening portions OP1-P, OP2-P and OP3-P, respectively.

The first emission pattern EP1 and the first cathode CE1 may be located in the first partition-wall-opening portion OP1-P, the second light-emitting element ED2 and the second cathode CE2 may be located in the second partition-wall-opening portion OP2-P, and the third light-emitting element ED3 and the third cathode CE3 may be located in the third partition-wall-opening portion OP3-P.

In one or more embodiments, the first to third emission patterns EP1, EP2, and EP3 and the first to third cathodes CE1, CE2, and CE3 may be physically separated by the second partition wall layer L2, which defines a tip portion, and defined in the emission-opening portions OP1-E, OP2-E, and OP3-E and the partition-wall-opening portions OP1-P, OP2-P, and OP3-P, respectively. Each of the first to third emission patterns EP1, EP2, and EP3 and the first to third cathodes CE1, CE2, and CE3 may contact at least a portion of the partition wall PW.

Each of the first to third emission patterns EP1, EP2, and EP3 may contact the lower partition wall layer L1-1 and may not be in contact with the upper partition wall layer L1-2. As the lower partition wall layer L1-1 corresponds to a high-resistance layer that is not substantially electrically conductive, the first to third emission patterns EP1, EP2, and EP3 may be in contact only with the lower partition wall layer L1-1 to prevent or reduce leakage current from being generated.

The first to third cathodes CE1, CE2, and CE3 may each contact the upper partition wall layer L1-2, and thus be electrically connected to each other to receive a common voltage. The upper partition wall layer L1-2 may have high electrical conductivity to reduce contact resistance with the first to third cathodes CE1, CE2, and CE3. Accordingly, a common cathode voltage may be substantially uniformly supplied to the emission areas PXA-R, PXA-G, and PXA-B.

According to one or more embodiments of the present disclosure, the plurality of emission patterns EP1, EP2, and EP3 may be deposited by being patterned into pixel units by the tip portion defined in the partition wall PW. That is, the plurality of emission patterns EP1, EP2, and EP3 may be formed in common using an open mask, but suitably separated into the pixel units by the partition wall PW.

In contrast, if a fine metal mask (FMM) is used to pattern the plurality of emission patterns EP1, EP2, and EP3, a support spacer protruding from a conductive partition wall may be provided to support the fine metal mask. In addition, as the fine metal mask is spaced a height of the partition wall and the spacer from a base surface that is subjected to patterning, achievement of high resolution may be restricted. Moreover, as the fine metal mask contacts the spacer, a foreign matter may remain on the spacer or the spacer may be damaged due to stabbing of the fine metal mask after a process of patterning the plurality of emission patterns EP1, EP2, and EP3. Accordingly, a defective display panel may be provided.

According to one or more embodiments, as the partition wall PW is included, physical separation between the light-emitting elements ED1, ED2, and ED3 may be achieved. Accordingly, drive errors or current leakage between adjacent emission areas PXA-R, PXA-G, and PXA-B may be prevented or reduced, and the light-emitting elements ED1, ED2, and ED3 may be each driven independently of each other.

For example, as the plurality of light-emitting elements ED1, ED2, and ED3 may be patterned without a mask contacting inner components in the display area DA (see FIG. 2), a defect rate may be reduced so that the display panel DP with improved process reliability is provided. As the patterning is enabled even if a separate support spacer protruding from the partition wall PW is not provided, the respective areas of the emission areas PXA-R, PXA-G, and PXA-B may be reduced or miniaturized to provide the display panel DP implemented at high resolution.

In addition, as manufacture of a mask having a large area is omitted from the manufacture of the display panel DP having a large area, process costs may be reduced, and the display panel DP may not be affected by a defect likely to occur in the mask having a large area. Accordingly, the display panel DP with improved process reliability may be provided. The description of the plurality of the first emission patterns EP1 may similarly apply to the plurality of the second and third emission patterns EP2 and EP3.

Capping patterns CP1, CP2, and CP3 may include a first capping pattern CP1, a second capping pattern CP2, and a third capping pattern CP3. The first to third capping patterns CP1, CP2, and CP3 may be located on the first to third cathode CE1, CE2, and CE3, respectively, and may be positioned within the first to third partition-wall-opening portions OP1-P, OP2-P, and OP3-P, respectively.

The dummy patterns DMP may include a plurality of first dummy patterns D1, a plurality of second dummy patterns D2, and a plurality of third dummy patterns D3.

The first dummy patterns D1 may include (1-1)-th to (1-3)-th dummy patterns D11, D12, and D13 surrounding the first to third emission areas PXA-R, PXA-G, and PXA-B, respectively, on a plane. The (1-1)-th to (1-3)-th dummy patterns D11, D12 and D13 may include the same materials as the first to third emission patterns EP1, EP2 and EP3, respectively, and may be formed through the same processes as the first to third emission patterns EP1, EP2 and EP3, respectively.

The second dummy patterns D2 may include (2-1)-th to (2-3)-th dummy patterns D21, D22, and D23 surrounding the first to third emission areas PXA-R, PXA-G, and PXA-B, respectively, on a plane. The (2-1)-th to (2-3)-th dummy patterns D21, D22, and D23 may include the same materials as the first to third cathodes CE1, CE2, and CE3, respectively, and may be formed through the same processes as the first to third cathodes CE1, CE2, and CE3, respectively.

The third dummy patterns D3 may include (3-1)-th to (3-3)-th dummy patterns D31, D32, and D33 surrounding the first to third emission areas PXA-R, PXA-G, and PXA-B, respectively, on a plane. The (3-1)-th to (3-3)-th dummy patterns D31, D32, and D33 may include the same materials as the first to third capping patterns CP1, CP2, and CP3, respectively, and may be formed through the same processes as the first to third capping patterns CP1, CP2, and CP3, respectively.

First to third dummy opening portions OP1-D, OP2-D, and OP3-D corresponding to the first to third emission-opening portions OP1-E, OP2-E, and OP3-E may be defined in the dummy patterns DMP, respectively. Each of the first to third dummy opening portions OP1-D, OP2-D, and OP3-D may include first to third regions AA1, AA2, and AA3 (see FIG. 10G) that are arranged in sequence in the third direction DR3. The first dummy opening portion OP1-D may be defined by inner side surfaces of the (1-1)-th, (2-1)-th, and (3-1)-th dummy patterns D11, D21 and D31, the second dummy opening portion OP2-D may be defined by inner side surfaces of the (1-2)-th, (2-2)-th, and (3-2)-th dummy patterns D12, D22 and D32, and the third dummy opening portion OP3-D may be defined by inner side surfaces of the (1-3)-th, (2-3)-th, and (3-3)-th dummy patterns D13, D23, and D33.

The thin film encapsulation layer TFE may include lower inorganic encapsulation patterns LIL1, LIL2, and LIL3, an organic encapsulation film OL, and an upper inorganic encapsulation film UIL. In one or more embodiments, the lower inorganic encapsulation patterns LIL1, LIL2, and LIL3 may include a first lower inorganic encapsulation pattern LIL1, a second lower inorganic encapsulation pattern LIL2, and a third lower inorganic encapsulation pattern LIL3. The first to third lower inorganic encapsulation patterns LIL1, LIL2, and LIL3 may overlap the first to third emission-opening portions OP1-E, OP2-E, and OP3-E, respectively.

The first lower inorganic encapsulation pattern LIL1 may cover the first light-emitting element ED1 and the (1-1)-th, (2-1)-th, and (3-1)-th dummy patterns D11, D21, and D31, and have a portion located inside the first partition-wall-opening portion OP1-P. The second lower inorganic encapsulation pattern LIL2 may cover the second light-emitting element ED2 and the (1-2)-th, (2-2)-th, and (3-2)-th dummy patterns D12, D22, and D32, and have a portion located inside the second partition-wall-opening portion OP2-P. The third lower inorganic encapsulation pattern LIL3 may cover the third light-emitting element ED3 and the (1-3)-th, (2-3)-th, and (3-3)-th dummy patterns D13, D23, and D33, and have a portion located inside the third partition-wall-opening portion OP3-P. The first to third lower inorganic encapsulation patterns LIL1, LIL2, and LIL3 may be provided in the form of patterns spaced apart from each other.

FIGS. 10A to 10I are cross-sectional views illustrating some of operations of a method for manufacturing a display panel according to one or more embodiments of the present disclosure. In the description with reference to FIGS. 10A to 10I, the same/similar reference numbers or symbols are used for the same/similar elements as/to those described with reference to FIGS. 1 to 9, and redundant description will be omitted.

The method for manufacturing the display panel according to one or more embodiments of the present disclosure may include providing a preliminary display panel DP-I, forming a first preliminary partition wall L1-I and a second preliminary partition wall L2-I, forming a partition wall PW, and forming an emission pattern EP and a cathode CE.

Referring to FIG. 10A, the method for manufacturing the display panel according to one or more embodiments may include providing a preliminary display panel DP-I. The preliminary display panel DP-I provided in one or more embodiments may include a base layer BL, a circuit element layer DP-CL, an anode AE, a preliminary sacrificial pattern SP-I, and a preliminary pixel-defining film PDL-I.

The circuit element layer DP-CL may be formed through a typical process for manufacture a circuit element by forming an insulation layer, a semiconductor layer, and a conductive layer through coating, deposition or the like, and then by selectively patterning the insulation layer, the semiconductor layer, and the conductive layer through a photolithography process and an etching process to form a semiconductor pattern, a conductive pattern, signal lines, and the like.

The anode AE and the preliminary sacrificial pattern SP-I may be formed through substantially the same patterning process. The preliminary pixel-defining film PDL-I may cover both the anode AE and the preliminary sacrificial pattern SP-I.

Then, referring to FIG. 10B, the method for manufacturing the display panel according to one or more embodiments may include forming a preliminary partition wall PW-I on the preliminary display panel DP-I. The forming of the preliminary partition wall PW-I may include forming a first preliminary partition wall layer L1-I and a second preliminary partition wall layer L2-I.

The first preliminary partition wall layer L1-I may be formed on the preliminary pixel-defining film PDL-I. The forming of the first preliminary partition wall layer L1-I may include forming a preliminary lower partition wall layer L1-1I and a preliminary upper partition wall layer L1-2I on the preliminary pixel-defining film PDL-I. The preliminary lower partition wall layer L1-1I and the preliminary upper partition wall layer L1-2I may be formed by depositing materials having substantially the same etch selectivity in sequence on the preliminary pixel-defining film PDL-I through a chemical vapor deposition (CVD) process.

The preliminary lower partition wall layer L1-1I may be formed by depositing an insulation material on the preliminary pixel-defining film PDL-I. For example, the insulation material used to form the preliminary lower partition wall layer L1-1I may include amorphous silicon (a-Si). The preliminary lower partition wall layer L1-1I may be formed by depositing amorphous silicon (a-Si) on the preliminary pixel-defining film PDL-I. The preliminary upper partition wall layer L1-2I may be formed by depositing a conductive material on the preliminary lower partition wall layer L1-1I. For example, the conductive material used to form the preliminary upper partition wall layer L1-2I may include n⁺ silicon (n⁺ Si). The preliminary upper partition wall layer L1-2I may be formed by depositing n⁺ silicon (n⁺ Si) on the preliminary lower partition wall layer L1-1I.

The second preliminary partition wall layer L2-I may be formed on the first preliminary partition wall layer L1-I. For example, the second preliminary partition wall layer L2-I may be formed on the preliminary upper partition wall layer L1-2I. The forming of the second preliminary partition wall layer L2-I may be performed through a process of depositing a conductive material. In one or more embodiments, the conductive material used to form the second preliminary partition wall layer L2-I may include a metal, a transparent conductive oxide (TCO), or a combination thereof. For example, the conductive material used to form the second preliminary partition wall layer L2-I may be gold (Au), silver (Ag), aluminum (Al), magnesium (Mg), lithium (Li), molybdenum (Mo), titanium (Ti), copper (Cu), or an alloy. The transparent conductive oxide used to form the second preliminary partition wall layer L2-I may include an indium tin oxide (ITO), an indium zinc oxide (IZO), a zinc oxide, an indium oxide, an indium gallium oxide, an indium gallium zinc oxide (IGZO), or an aluminum zinc oxide. The conductive material used to form the second preliminary partition wall layer L2-I may be different from the conductive material used to form the preliminary upper partition wall layer L1-2I. The conductive material used to form the second preliminary partition wall layer L2-I may include at least one of molybdenum (Mo) or titanium (Ti). In one or more embodiments, the second preliminary partition wall layer L2-I may be formed from molybdenum (Mo).

Thereafter, the method for manufacturing the display panel according to one or more embodiments may include forming a first photoresist layer PR1 (see FIG. 10C) on the preliminary partition wall PW-I.

Referring to FIG. 10C, the first photoresist layer PR1 may be formed by forming a preliminary photoresist layer on the preliminary partition wall PW-I and then patterning the preliminary photoresist layer by using a photo mask. A photo-opening portion OP-PR may be formed in the first photoresist layer PR1 through a patterning process. The photo-opening portion OP-PR may overlap the anode AE on a plane.

Then, referring to FIGS. 10D and 10E, the method for manufacturing the display panel according to one or more embodiments may include etching the first preliminary partition wall layer L1-I and the second preliminary partition wall layer L2-I to form a first partition wall layer L1 and a second partition wall layer L2, in which a partition-wall-opening portion OP-P is defined, so that a partition wall PW is formed from the preliminary partition wall PW-I.

First, as illustrated in FIG. 10D, primary etching of the first preliminary partition wall layer L1-I and the second preliminary partition wall layer L2-I may include forming a preliminary partition-wall-opening portion OP-PI in the preliminary partition wall PW-I by using the first photoresist layer PR1 as a mask and dry etching the first preliminary partition wall layer L1-I and the second preliminary partition wall layer L2-I. The first preliminary partition wall layer L1-I and the second preliminary partition wall layer L2-I may be etched at substantially the same time through a primary dry etching process. The preliminary partition-wall-opening portion OP-PI may overlap the anode AE.

The primary dry etching process according to one or more embodiments may be performed in an etching environment in which etch selectivities of the first preliminary partition wall layer L1-I and the second preliminary partition wall layer L2-I are substantially the same. Accordingly, the inner side surface of the first preliminary partition wall layer L1-I and the inner side surface of the second preliminary partition wall layer L2-I, each of which defines the preliminary partition-wall-opening portion OP-PI, may be substantially aligned with each other.

Then, as illustrated in FIG. 10E, secondary etching of the first preliminary partition wall layer L1-I may include forming a partition-wall-opening portion OP-P from the preliminary partition-wall-opening portion OP-PI (see FIG. 10D) by using the first photoresist layer PR1 as a mask and dry etching the first preliminary partition wall layer L1-I. The partition-wall-opening portion OP-P may overlap a first anode AE1. In the present disclosure, secondary dry etching of the first preliminary partition wall layer L1-I may be referred to as an “undercut etching process”.

In the undercut etching process, the preliminary lower partition wall layer L1-1I and the preliminary upper partition wall layer L1-2I may be etched at substantially the same time. In addition, the undercut etching process may be performed in an etching environment in which etch selectivities of the preliminary lower partition wall layer L1-1I and the preliminary upper partition wall layer L1-2I are substantially the same. Accordingly, the inner side surface of the lower partition wall layer L1-1 and the inner side surface of the upper partition wall layer L1-2, each of which defines the partition-wall-opening portion OP-P, may be substantially aligned with each other.

The partition-wall-opening portion OP-P may include a first region A1 and a second region A2 that are positioned in sequence in a thickness direction (e.g., third direction DR3). The first partition wall layer L1 may have a first inner side surface S-L1 that defines the first region A1 of the partition-wall-opening portion OP-P. The first inner side surface S-L1 may be divided into an inner side surface S-L11 of the lower partition wall layer L1-1 and an inner side surface S-L12 of the upper partition wall layer L1-2. The second partition wall layer L2 may have a second inner side surface S-L2 that defines the second region A2.

The undercut etching process according to one or more embodiments may be performed in an etching environment in which a difference in etch selectivity between the first preliminary partition wall layer L1-I and the second preliminary partition wall layer L2-I is suitably large. Accordingly, the inner side surface of the partition wall PW that defines the partition-wall-opening portion OP-P may have an undercut shape on a cross section. In one or more embodiments, an etch rate of the first preliminary partition wall layer L1-I may be higher than an etch rate of the second preliminary partition wall layer L2-I. The etch rate of each of the preliminary lower partition wall layer L1-1I and the preliminary upper partition wall layer L1-2I may be higher than an etch rate of the second preliminary partition wall layer L2-I. That is, the second preliminary partition wall layer L2-I may include a material having a lower etch rate than that of the first preliminary partition wall layer L1-I. Accordingly, the first preliminary partition wall layer L1-I may be more etched than the second preliminary partition wall layer L2-I, and a first inner side surface S-L1 of the first partition wall layer L1 may be recessed from a second inner side surface S-L2 of the second partition wall layer L2 toward a center of the first partition wall layer L1. A tip portion may be formed in the partition wall PW by a portion of the second partition wall layer L2, which protrudes from the first partition wall layer L1 toward a center of the anode AE (e.g., in a plan view).

Thereafter, referring to FIG. 10F, the method for manufacturing the display panel according to one or more embodiments may include etching the preliminary pixel-defining film PDL-I (see FIG. 10E) so that a pixel-defining film PDL is formed. The etching of the preliminary pixel-defining film PDL-I (see FIG. 10E) may be performed using a dry etching method, and the preliminary pixel-defining film PDL-I (see FIG. 10E) may be etched using, as a mask, the first photoresist layer PR1 and a portion of the partition wall PW (e.g., the second partition wall layer L2). An emission-opening portion OP-E corresponding to the partition-wall-opening portion OP-P may be formed in the pixel-defining film PDL.

In addition, the method for manufacturing the display panel according to one or more embodiments may include etching the preliminary sacrificial pattern SP-I. The etching of the preliminary sacrificial pattern SP-I may be performed using a wet etching method, for example, and the preliminary sacrificial pattern SP-I may be etched using, as a mask, the first photoresist layer PR1 and a portion of the partition wall PW, (e.g., the second partition wall layer L2).

Referring to FIG. 10G, a sacrificial-opening portion OP-S overlapping the emission-opening portion OP-E may be formed in a sacrificial pattern SP formed by etching the preliminary sacrificial pattern SP-I. At least a portion of the anode AE may be exposed from the sacrificial pattern SP and the pixel-defining film PDL by the sacrificial-opening portion OP-S and the emission-opening portion OP-E. The sacrificial pattern SP may include an amorphous transparent conductive oxide. For example, the sacrificial pattern SP may be a zinc oxide (ZnOₓ) doped with aluminum (Al).

The etching of the sacrificial pattern SP may be performed in an etching environment, in which a difference in etch selectivity between the sacrificial pattern SP and the anode AE is suitably large, and accordingly the anode AE may be prevented from being etched together. That is, the sacrificial pattern SP having a higher etch rate than the anode AE may be positioned between the pixel-defining film PDL and the anode AE so that the anode AE may be prevented from being etched together and damaged during the etching.

In addition, the etching of the sacrificial pattern SP may be performed in an etching environment, in which a difference in etch selectivity between the sacrificial pattern SP and the first and second partition wall layer L1 and L2 of the partition wall PW is relatively large, and accordingly, the likelihood of the first and second partition wall layer L1 and L2 being etched together may be reduced or prevented.

The method for manufacturing the display panel according to one or more embodiments may include forming an emission pattern EP in the partition-wall-opening portion OP-P, forming a cathode CE, and forming a capping pattern CP, after the first photoresist layer PR1 (see FIG. 10F) is removed.

The forming of the emission pattern EP, the forming of the cathode CE, and the forming of the capping pattern CP may each be performed through a deposition process. In one or more embodiments, the forming of the emission pattern EP may be performed through a thermal evaporation process, the forming of the cathode CE may be performed through a sputtering process, and the forming of the capping pattern CP may be performed through the thermal evaporation process. However, one or more embodiments of the present disclosure is not limited thereto.

In the forming of the emission pattern EP, the emission pattern EP may be separated by a tip portion formed in the partition wall PW, and may be located inside the emission-opening portion OP-E and the partition-wall-opening portion OP-P. In the forming of the emission pattern EP, a first preliminary dummy pattern D1-I spaced apart from the emission pattern EP may be formed together on the partition wall PW.

In one or more embodiments, the emission pattern EP may contact the lower partition wall layer L1-1 and not in contact with the upper partition wall layer L1-2. Accordingly, the display panel DP (see FIG. 9) according to one or more embodiments may prevent or reduce leakage current from being generated between adjacent pixels.

In the forming of the cathode CE, the cathode CE may be separated by the tip portion formed in the partition wall PW, and may be located inside the partition-wall-opening portion OP-P. The cathode CE may be provided at a higher angle of incidence than the emission pattern EP so that the cathode CE contacts the first inner side surface S-L1 (see FIG. 10E) of the first partition wall layer L1. For example, the cathode CE contact the inner side surface S-L11 (see FIG. 10E) of the lower partition wall layer L1-1. In addition, at least a portion of the cathode CE contact the inner side surface S-L12 (see FIG. 10E) of the upper partition wall layer L1-2. In the forming of the cathode CE, a second preliminary dummy pattern D2-I spaced apart from the cathode CE may be formed together on the partition wall PW. The anode AE, the emission pattern EP, and the cathode CE may constitute a light-emitting element ED.

In the forming of the capping pattern CP, the capping pattern CP may be separated by the tip portion formed in the partition wall PW, and may be located inside the partition-wall-opening portion OP-P. In the forming of the capping pattern CP, a third preliminary dummy pattern D3-I spaced apart from the capping pattern CP may be formed together on the partition wall PW. According to another embodiment of the present disclosure, the forming of the capping pattern CP may be omitted.

The first to third preliminary dummy patterns D1-I, D2-I, and D3-I may form a preliminary dummy pattern DMP-I, and a dummy opening portion OP-D may be defined in the preliminary dummy pattern DMP-I. The dummy opening portion OP-D may include a first region AA1, a second region AA2, and a third region AA3 that are positioned in sequence in a thickness direction (e.g., third direction DR3). In the dummy opening portion OP-D, the first region AA1 may be defined by an inner side surface of the first preliminary dummy pattern D1-I, the second region AA2 may be defined by an inner side surface of the second preliminary dummy pattern D2-I, and the third region AA3 may be defined by an inner side surface of the third preliminary dummy pattern D3-I.

Thereafter, referring to FIG. 10H, the method for manufacturing the display panel according to one or more embodiments may include forming a preliminary lower inorganic encapsulation pattern LIL-1. The preliminary lower inorganic encapsulation pattern LIL-1 may be formed through a deposition process. In one or more embodiments, the preliminary lower inorganic encapsulation pattern LIL-1 may be formed through a chemical vapor deposition (CVD) process. The preliminary lower inorganic encapsulation pattern LIL-1 may be formed by depositing a silicon nitride (SiNₓ) on the partition wall PW and the cathode CE, and a portion of the preliminary lower inorganic encapsulation pattern LIL-1 may be formed inside the partition-wall-opening portion OP-P. In one or more embodiments, the lower inorganic encapsulation pattern LIL (see FIG. 7) formed from the silicon nitride (SiNₓ) may provide characteristics of being very resistant to moisture due to high bonding force with the lower partition wall layer L1-1 and the upper partition wall layer L1-2 of the first partition wall layer L1 (see FIG. 10G).

Then, referring to FIG. 10I, the method for manufacturing the display panel according to one or more embodiments may include forming a second photoresist layer PR2, patterning the preliminary lower inorganic encapsulation pattern LIL-1 (see FIG. 10H) so that the lower inorganic encapsulation pattern LIL is formed, and patterning the preliminary dummy patterns DMP-I (see FIG. 10H) so that dummy patterns DMP are formed.

In the forming of the second photoresist layer PR2, the second photoresist layer PR2 may be formed by forming a preliminary photoresist layer, and then patterning the preliminary photoresist layer by using a photo mask. The second photoresist layer PR2 have a pattern shape corresponding to the emission-opening portion OP-E through the patterning process.

Referring back to FIG. 10H, in the patterning of the preliminary lower inorganic encapsulation pattern LIL-1, the preliminary lower inorganic encapsulation pattern LIL-1 may be patterned through dry etching so that a portion of the preliminary lower inorganic encapsulation pattern LIL-1, which overlaps remaining anodes except the corresponding anode AE, is removed. For example, if the preliminary lower inorganic encapsulation pattern LIL-1 corresponds to the first anode AE1 (see FIG. 9), a portion of the preliminary lower inorganic encapsulation pattern LIL-1, which overlaps the second and third anodes AE2 and AE3 (see FIG. 9), may be removed.

The lower inorganic encapsulation pattern LIL overlapping a corresponding emission-opening portion OP-E may be formed from the patterned preliminary lower inorganic encapsulation pattern LIL-1. A portion of the lower inorganic encapsulation pattern LIL may be located in the partition-wall-opening portion OP-P to cover the light-emitting element ED, and another portion of the lower inorganic encapsulation pattern LIL may be located on the partition wall PW.

In the patterning of the preliminary dummy patterns DMP-I, the first to third preliminary dummy patterns D1-I, D2-I, and D3-I may be patterned through dry etching so that a portion of each of the first to third preliminary dummy patterns D1-I, D2-I, and D3-I, which overlaps remaining anodes except the corresponding anode AE, is removed. For example, when the first to third preliminary dummy patterns D1-I, D2-I, and D3-I correspond to the first anode AE1 (see FIG. 9), a portion of each of the first to third preliminary dummy patterns D1-I, D2-I, and D3-I, which overlaps the second and third anodes AE2 and AE3 (see FIG. 9), may be removed.

First to third dummy patterns D1, D2, and D3 overlapping a corresponding emission-opening portion OP-E may be formed from the patterned first to third preliminary dummy patterns D1-I, D2-I, and D3-I, respectively, and form the dummy patterns DMP, each of which may include the first to third dummy patterns D1, D2, and D3. Each of the first to third dummy patterns D1, D2, and D3 may have a closed line shape surrounding the emission area PXA (see FIG. 7) on a plane.

Thereafter, referring to FIGS. 7 and 10I together, the method for manufacturing the display panel according to one or more embodiments may include forming an organic encapsulation film OL and an upper inorganic encapsulation film UIL to finish the display panel DP, after the second photoresist layer PR2 is removed. The organic encapsulation film OL may be formed by applying an organic material through an inkjet process, but is not limited thereto. The organic encapsulation film OL provides a planarized top surface. Thereafter, an inorganic material may be deposited to form the upper inorganic encapsulation film UIL. Accordingly, the display panel DP may be formed which may include a base layer BL, a circuit element layer DP-CL, a display element layer DP-OLED, and a thin film encapsulation layer TFE.

Forming a partition-wall-opening portion and an emission-opening portion, each of which corresponds to an emission area having a different color, in the partition wall PW and the pixel-defining film PDL, forming light-emitting elements ED1, ED2, and ED3 that provide different colors, and forming a lower inorganic encapsulation pattern LIL that covers the light-emitting elements ED1, ED2, and ED3 that provide the different colors, may be further performed between the forming of the lower inorganic encapsulation pattern LIL and the finishing of the display panel DP. Accordingly, the display panel DP may be formed which may include first to third light-emitting elements ED1, ED2, and ED3, first to third capping patterns CP1, CP2, and CP3, (1-1)-th to (1-3)-th dummy patterns D1-1, D1-2, and D1-3, (2-1)-th to (2-3)-th dummy patterns D2-1, D2-2, and D2-3, (3-1)-th to (3-3)-th dummy patterns D3-1, D3-2, and D3-3, and first to third lower inorganic encapsulation patterns LIL1, LIL2, and LIL3, as illustrated in FIG. 9.

The display panel according to one or more embodiments may include the partition wall PW including the first partition wall layer L1 including the insulation material, and the second partition wall layer L2 including the conductive material. Here, the emission pattern EP included in the light-emitting element ED may contact only the first partition wall layer L1. Thus, even if the portion (e.g., organic layer doped with the p-type dopant) of the emission pattern EP has conductivity, the leakage current may be prevented or reduced.

According to the method for manufacturing the display panel according to one or more embodiments, the leakage current between the adjacent pixels may be prevented or reduced, thereby manufacturing the display panel that exhibits suitable display quality.

Although one or more embodiments of the present disclosure have been described, it is understood that the present disclosure should not be limited to these embodiments but various changes and modifications can be made by one ordinary skilled in the art within the spirit and scope of the present disclosure as hereinafter claimed, with functional equivalents thereof to be included therein. Therefore, the technical scope of the present disclosure is not limited to the contents described in the detailed description of the specification, but should be determined by the claims.

What is claimed is:

1. A display panel comprising:
a base layer;
a pixel-defining film above the base layer, and defining an emission-opening portion;
a partition wall comprising:
a first partition wall layer above the pixel-defining film, and comprising a lower partition wall layer comprising an insulation material, and an upper partition wall layer comprising a conductive material above the lower partition wall layer; and
a second partition wall layer above the first partition wall layer and defining a partition-wall-opening portion overlapping the emission-opening portion; and
a light-emitting element comprising an anode, an intermediate layer contacting the lower partition wall layer and spaced apart from the upper partition wall layer above the anode, and a cathode above the intermediate layer.

2. The display panel of claim 1, wherein the lower partition wall layer comprises amorphous silicon (a-Si), and
wherein the upper partition wall layer comprises n⁺ silicon (n⁺ Si).

3. The display panel of claim 1, wherein the intermediate layer comprises at least one organic layer doped with a p-type dopant.

4. The display panel of claim 3, wherein the intermediate layer comprises:
a hole transport region comprising the organic layer doped with the p-type dopant above the anode;
an emission layer above the hole transport region; and
an electron transport region above the emission layer.

5. The display panel of claim 3, wherein the intermediate layer comprises:
emission structures above the anode; and
a charge generation layer between the emission structures and comprising the organic layer doped with the p-type dopant.

6. The display panel of claim 1, wherein the lower partition wall layer has a thickness that is less than about 0.5 times a thickness of the first partition wall layer.

7. The display panel of claim 1, wherein the cathode contacts the upper partition wall layer, and is electrically connected to the partition wall.

8. The display panel of claim 1, wherein the second partition wall layer comprises a tip portion protruding from the first partition wall layer toward the partition-wall-opening portion.

9. The display panel of claim 1, wherein the second partition wall layer comprises at least one of molybdenum or titanium.

10. The display panel of claim 1, further comprising a thin film encapsulation layer comprising thin films above the light-emitting element, and comprising a lower inorganic encapsulation pattern covering the light-emitting element and contacting the partition wall.

11. The display panel of claim 10, wherein the lower inorganic encapsulation pattern comprises silicon nitride (SiNₓ).

12. The display panel of claim 1, wherein the partition-wall-opening portion comprises:
a first region in which the light-emitting element is located; and
a second region having a width that is less than a width of the first region,
wherein the first partition wall layer has a first inner side surface defining the first region, and
wherein the second partition wall layer has a second inner side surface defining the second region.

13. A display panel comprising:
a base layer;
a pixel-defining film above the base layer and defining an emission-opening portion;
a partition wall above the pixel-defining film, defining a partition-wall-opening portion corresponding to the emission-opening portion, and comprising:
a lower partition wall layer comprising amorphous silicon (a-Si);
an upper partition wall layer above the lower partition wall layer, and comprising n⁺ silicon (n⁺ Si); and
a second partition wall layer above the upper partition wall layer, and comprising a tip portion protruding from the lower partition wall layer and the upper partition wall layer toward the partition-wall-opening portion; and
a light-emitting element in the partition-wall-opening portion in plan view, and comprising an anode, an intermediate layer above the anode, and a cathode above the intermediate layer.

14. The display panel of claim 13, wherein the intermediate layer contacts the lower partition wall layer and is spaced apart from the upper partition wall layer, and
wherein the cathode contacts the upper partition wall layer.

15. The display panel of claim 13, further comprising a sacrificial pattern between the anode and the pixel-defining film, and defining a sacrificial-opening portion overlapping the emission-opening portion.

16. The display panel of claim 13, wherein a thickness of the lower partition wall layer is less than a thickness of the upper partition wall layer.

17. A method for manufacturing a display panel, the method comprising:
providing a preliminary display panel comprising a base layer, an anode above the base layer, and a pixel-defining film above the base layer and covering the anode;
forming a first preliminary partition wall layer by depositing an insulation material and a conductive material having substantially equal etch selectivity above the preliminary display panel;
forming a second preliminary partition wall layer above the preliminary display panel;
etching the first preliminary partition wall layer and the second preliminary partition wall layer to form a partition wall defining a partition-wall-opening portion; and
forming an emission pattern and a cathode in the partition-wall-opening portion.

18. The method of claim 17, wherein the insulation material comprises amorphous silicon (a-Si), and the conductive material comprises n⁺ silicon (n⁺ Si).

19. The method of claim 17, wherein the second preliminary partition wall layer comprises a conductive material having a lower etch rate than the first preliminary partition wall layer.

20. The method of claim 17, further comprising etching the first preliminary partition wall layer and the second preliminary partition wall layer at a substantially same time through dry etching.
